(19) United States
(12) Patent Application Publication
(10) Pub. No.: US 2025/0293146 A1
(43) Pub. Date: Sep. 18, 2025

(54) STACKED METAL-OXIDE-METAL (MOM) CAPACITOR(S) IN FRONT SIDE AND BACK SIDE METALLIZATION LAYER(S) OF SEMICONDUCTOR DIE, AND RELATED INTEGRATED CIRCUIT (IC) PACKAGES AND FABRICATION METHODS

(71) Applicant: QUALCOMM Incorporated, San Diego, CA (US)

(72) Inventors: John Jianhong Zhu, San Diego, CA (US); Junjing Bao, San Diego, CA (US); Lixin Ge, San Diego, CA (US)

(21) Appl. No.: 18/604,993

(22) Filed: Mar. 14, 2024

(51) Int. Cl. H01L 23/522

(52) U.S. Cl. CPC H01L 23/5223

(57) ABSTRACT

Stacked metal-oxide-metal (MoM) capacitor(s) in front side and back side metallization layers of a semiconductor die, and related fabrication methods. The stacked MoM capacitor includes a first, front side, MoM capacitor formed on the front side of the semiconductor layer of a die and in front side metallization layers in a front side interconnect structure. The stacked MoM capacitor also includes a second, back side MoM capacitor formed on the back side of the semiconductor layer in back side metallization layers in a back side interconnect structure. The front side and back side MoM capacitors are coupled to each other through a conducting structure in a second, vertical direction between the front side and back side interconnect structures to form the stacked MoM capacitor. In this manner, capacitance density in the die can be maintained or increase while providing sufficient area in the front side metallization layers for signal routing.

### TECHNICAL FIELD

The field of the disclosure relates to a semiconductor die (“die”) that can be incorporated into an integrated circuit (IC) package, wherein the die includes a metal-oxide-metal (MoM) capacitor(s) formed in metallization layers of an interconnect structure of the die.

### BACKGROUND

Computing devices have become increasingly common in modern society. Early computers were the size of a room and employed vacuum tubes to provide rudimentary mathematical calculations. In contrast, modern computing devices provide myriad multimedia, telephony, word processing, and other functions in a relatively small package relying on integrated circuits (ICs). The industry feels market pressure to provide ever increasing processing options in increasingly smaller products. While ICs have generally obeyed Moore's Law, continued advances in IC functionality in a smaller package is stressing manufacturing capabilities.

Current IC manufacturing processes rely on sequences of masks used in stages to create multi-level ICs. ICs, which are provided in the form of a semiconductor die (“die”), include an active semiconductor layer conventionally fabricated in a front-end-of-line (FEOL) fabrication process. The active semiconductor layer includes semiconductor devices (e.g., transistors). The die also includes an interconnect structure formed adjacent to the semiconductor layer, on a “front side” of the semiconductor layer, typically through a back-end-of-line (BEOL) fabrication process. The interconnect structure includes multiple metallization layers each with metal lines (e.g., metal traces) disposed in a respective metallization layer to provide interconnections between different semiconductor devices and/or external interconnects (e.g., solder balls). Vertical interconnect accesses (vias), such as metal pillars and through-silica-vias (TSVs), are disposed in the metallization layers to provide interconnections between adjacent metal lines in adjacent metallization layers. A power distribution network (PDN) that includes power and ground nodes can also be provided in the interconnect structure using multiple metal lines over multiple metallization layers to distribute power to active devices formed in the semiconductor layer. Metal lines formed in the metallization layers of the interconnect can also be used to form passive devices, such as capacitors (e.g., metal-oxide-metal (MoM) capacitors). As an example, the structure of a MoM capacitor can provide a high capacitance in a reduced area of the die to provide a high capacitance density in the die. For example, these capacitors may be used to provide a decoupling capacitance between power and ground notes of the PDN in the die or to otherwise provide capacitance coupled to an active device(s) formed in the semiconductor layer as part of a circuit.

### SUMMARY OF THE DISCLOSURE

Aspects disclosed herein include stacked metal-oxide-metal (MoM) capacitors in front side and back side metallization layers of a semiconductor die (“die”). Related methods of fabricating the stacked MoM capacitor(s) in the die are also disclosed. In an example, the MoM capacitor is a structure that has generally interdigitated conductive finger structures formed from metal lines or traces in a metallization layer that extends in a first, horizontal direction. Multiple MoM capacitors can be formed in multiple metallization layers and coupled to each other to increase capacitance density. In this regard, in exemplary aspects, the stacked MoM capacitor includes a first, front side, MoM capacitor formed adjacent to the front side of the semiconductor layer of a die and as at least part of a front side metallization layer(s) of a front side interconnect structure (e.g., a back-end-of-line (BEOL) interconnect structure formed by a BEOL process). The stacked MoM capacitor also includes a second, back side MoM capacitor formed adjacent to the back side of the semiconductor layer as at least part of a back side metallization layer(s) of a back side interconnect structure. The first, front side MoM capacitor and second, back side MoM capacitor are coupled to each other through a conducting structure(s) (e.g., metal contact(s), via(s), gate(s), semiconductor device(s)) that extends in a second, vertical direction between the front side and back side interconnect structures to form the stacked MoM capacitor. By using both front side and back side metallization layers for the formation of the stacked MoM capacitor in the die, area in the front side metallization layers of the die that would otherwise be used as part of the stacked MoM capacitor can be conserved and used for other signal routing in the die. In this manner, as an example, the capacitance density in the die can be maintained or increase while providing sufficient area in the front side metallization layers for signal routing. Fabrication processes that are used to otherwise form metal lines in front side and back side interconnect structures in a die with through vias and/or contacts can be employed to form the stacked MoM capacitor.

Also, as another example, if a power distribution network (PDN) is provided in the back side metallization layers of a die, the second, back side MoM capacitor formed in the back side metallization layer(s) can be more closely located to the node of the PDN. This PDN can be provided in backside metallization layers of the die and can save area from being consumed in front side metallization layers of the die to avoid the need to add or increase metallization layers in the front side. Forming a MoM capacitor as part of the stacked MoM capacitor as at least part of the back side interconnect structure closely located to a PDN formed in the back side interconnect structure can provide a lower coupling resistance and inductance between the stacked MoM capacitor and the PDN for improved decoupling capacitance and reduced current-resistance (IR) drop.

In one exemplary aspect, the first, front side and second, back side MoM capacitors of the stacked MoM capacitor are coupled directly to each other through metal contacts coupled to a via(s) that extends in the second, vertical direction between the front side and back side interconnect structures.

In another exemplary aspect, the first, front side and second, back side MoM capacitors of the stacked MoM capacitor can be coupled to each other through a semiconductor device formed in the semiconductor layer of the die between the front side and back side interconnect structures. For example, the semiconductor device can be formed as a P-type semiconductor material and N-type semiconductor material junction device (e.g., a P-N junction capacitor). The semiconductor device may also be formed as a gate-controlled device (e.g., a variable capacitor). If a semiconductor device formed in the semiconductor layer used to couple the first, front side MoM capacitor and the second, back side MoM capacitor is a capacitor, the capacitor can provide additional capacitance in the stacked MoM capacitor to provide even higher capacitance density.

In another exemplary aspect, the first, front side and second, back side MoM capacitors of the stacked MoM capacitor are coupled to each other through a fixed metal contact(s) that directly extends between the front side and back side interconnect structures.

In another exemplary aspect, the first, front side and second, back side MoM capacitors of the stacked MoM capacitor are coupled to each other through a deep via structure(s) that directly extends between the front side and back side interconnect structures.

In another exemplary aspect, the first, front side and second, back side MoM capacitors of the stacked MoM capacitor are coupled to each other through a through-silicon-via (TSV) that extends in the second, vertical direction between the front side and back side interconnect structures and through the semiconductor layer of the die.

In another exemplary aspect, the first, front side and second, back side MoM capacitors of the stacked MoM capacitor are coupled to each other using a gate(s) in the semiconductor layer, wherein the gate is coupled to the front side and back side interconnect structures through metal contacts.

In this regard, in one exemplary aspect, a semiconductor die is provided. The semiconductor die comprises a semiconductor layer extending in a first direction. The semiconductor layer comprises a front side and a back side opposite the front side in a second direction orthogonal to the first direction. The semiconductor die also comprises a front side interconnect structure adjacent to the front side of the semiconductor layer in the second direction. The semiconductor die also comprises a back side interconnect structure adjacent to the back side of the semiconductor layer in the second direction. The semiconductor die also comprises a stacked MoM capacitor, comprising a first MoM capacitor as at least part of the front side interconnect structure, and a second MoM capacitor as at least part of the back side interconnect structure and coupled to the first MoM capacitor.

In another exemplary aspect, a method of fabricating a semiconductor die is provided. The method comprises forming a semiconductor layer extending in a first direction, the semiconductor layer comprising a front side and a back side opposite the front side in a second direction orthogonal to the first direction. The method also comprises forming a front side interconnect structure adjacent to the front side of the semiconductor layer in the second direction. The method also comprises forming a back side interconnect structure adjacent the back side of the semiconductor layer in the second direction. The method also comprises forming a stacked metal-oxide-metal (MoM) capacitor, comprising forming a first MoM capacitor as at least part of the front side interconnect structure, and forming a second MoM capacitor as at least part of the back side interconnect structure and coupled to the first MoM capacitor.

### BRIEF DESCRIPTION OF THE FIGURES

FIG. 1 is a side view of an integrated circuit (IC) that includes a semiconductor die (“die”) stack that includes a front side, back-end-of-line (BEOL) interconnect structure that includes first, front side metallization layers for signal routing and a back side, interconnect structure that includes second back side, metallization layers for signal routing;

FIG. 2 is a top view of an exemplary stacked metal-oxide-metal (MoM) capacitor that can be provided in an interconnect structure of a die like in FIG. 1, wherein the stacked MoM capacitor includes a first, overlying metallization layer that includes a first MoM capacitor electrically coupled to a second MOM capacitor in an adjacent second, underlying metallization layer;

FIG. 3A is a top view of an exemplary die that includes a stacked MoM capacitor similar to the stacked MoM capacitor in FIG. 2, but that includes a first, front side, MoM capacitor formed adjacent to the front side of the semiconductor layer of the die and in front side metallization layers in a front side interconnect structure, coupled to a second, back side MoM capacitor formed adjacent to the back side of the semiconductor layer of the die in back side metallization layers in a back side interconnect structure;

FIG. 3B is cross-sectional side view of the die in FIG. 3A illustrating a first conductive finger structure of the first, front side, MoM capacitor of the stacked MoM capacitor coupled through a semiconductor device in the form of a capacitor with a diffusion region in a semiconductor layer, to a first metal finger structure of the second, back side, MoM capacitor of the stacked MoM capacitor;

FIG. 3C is cross-sectional side view of the die in FIG. 3A illustrating a second conductive finger structure of the first, front side, MoM capacitor of the stacked MoM capacitor coupled through a gate, to a second conductive finger structure of the second, back side, MoM capacitor of the stacked MoM capacitor;

FIG. 3D is cross-sectional side view of the die in FIG. 3A illustrating a first conductive finger structure of the first, front side, MoM capacitor of the stacked MoM capacitor coupled through a fixed metal contact, to a first metal finger structure of the second, back side, MoM capacitor of the stacked MoM capacitor;

FIG. 3E is cross-sectional side view of the die in FIG. 3A illustrating a second conductive finger structure of the first, front side, MoM capacitor of the stacked MoM capacitor coupled through a deep bar via, to a second metal finger structure of the second, back side, MoM capacitor of the stacked MoM capacitor;

FIGS. 4A and 4B are top views illustrating exemplary relaxed and tighter process margins that can be provided in the die in FIG. 3A for coupling the first, front side, MoM capacitor of the stacked MoM capacitor to the second, back side, MoM capacitor;

FIG. 5A is a top view of another exemplary die that includes another stacked MoM capacitor similar to the stacked MoM capacitor in FIGS. 3A-3D, but that includes a first, front side, MoM capacitor formed adjacent to the front side of the semiconductor layer of the die and in front side metallization layers in a front side interconnect structure, coupled outside of a diffusion region to a second, back side MoM capacitor formed adjacent to the back side of the semiconductor layer of the die in back side metallization layers in a back side interconnect structure;

FIG. 5B is cross-sectional side view of the die in FIG. 5A illustrating the first, front side, MoM capacitor of the stacked MoM capacitor coupled through a deep bar via(s), to the second, back side, MoM capacitor of the stacked MoM capacitor;

FIG. 5C is another cross-sectional side view of the die in FIG. 5A illustrating the first, front side, MoM capacitor of the stacked MoM capacitor coupled through a deep bar via(s), to a second, back side, MoM capacitor of the stacked MoM capacitor;

FIG. 6 is a flowchart illustrating an exemplary process of fabricating a die that includes fabricating a stacked MoM capacitor that includes a first, front side, MoM capacitor formed adjacent to a front side of a semiconductor layer of the die and in front side metallization layers in a front side interconnect structure, coupled to a second, back side MoM capacitor formed adjacent to a back side of the semiconductor layer of the die in back side metallization layers in a back side interconnect structure, including, but not limited to, the stacked MoM capacitors in FIGS. 3A-5C;

FIGS. 7A-7H is a flowchart illustrating an exemplary fabrication process of fabricating the stacked MoM capacitor in the die in FIGS. 3A-5C;

FIGS. 8A-8H are exemplary fabrication stages during fabrication of the stacked MoM capacitor according to the exemplary fabrication process in FIGS. 7A-7H;

FIG. 9 is a block diagram of an exemplary wireless communications device that includes one or more dies that include a stacked MoM capacitor(s) that includes a first, front side, MoM capacitor formed adjacent to a front side of a semiconductor layer of the die and in front side metallization layers in a front side interconnect structure, coupled to a second, back side MoM capacitor formed adjacent to a back side of the semiconductor layer of the die in back side metallization layers in a back side interconnect structure, including, but not limited to, the stacked MoM capacitors in FIGS. 3A-5C and 8H, and that can be fabricated according to a fabrication process, including, but not limited to, the exemplary fabrication processes in FIGS. 6-7H; and

FIG. 10 is a block diagram of an exemplary electronic device in the form of a processor-based system that includes one or more dies that include a stacked MoM capacitor(s) that includes a first, front side, MoM capacitor formed adjacent to a front side of a semiconductor layer of the die and in front side metallization layers in a front side interconnect structure, coupled to a second, back side MoM capacitor formed adjacent to a back side of the semiconductor layer of the die in back side metallization layers in a back side interconnect structure, including, but not limited to, the stacked MoM capacitors in FIGS. 3A-5C and 8H, and that can be fabricated according to a fabrication process, including, but not limited to, the exemplary fabrication processes in FIGS. 6-7H.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include stacked metal-oxide-metal (MoM) capacitors in front side and back side metallization layers of a semiconductor die (“die”). Related methods of fabricating the stacked MoM capacitor(s) in the die are also disclosed. In an example, the MoM capacitor is a structure that has generally interdigitated conductive finger structures formed from metal lines or traces in a metallization layer that extends in a first, horizontal direction. Multiple MoM capacitors can be formed in multiple metallization layers and coupled to each other to increase capacitance density. In this regard, in exemplary aspects, the stacked MoM capacitor includes a first, front side, MoM capacitor formed adjacent to the front side of the semiconductor layer of a die and as at least part of a front side metallization layer(s) of a front side interconnect structure (e.g., a back-end-of-line (BEOL) interconnect structure formed by a BEOL process). The stacked MoM capacitor also includes a second, back side MoM capacitor formed adjacent to the back side of the semiconductor layer as at least part of a back side metallization layer(s) of a back side interconnect structure. The first, front side MoM capacitor and second, back side MoM capacitor are coupled to each other through a conducting structure(s) (e.g., metal contact(s), via(s), gate(s), semiconductor device(s)) that extends in a second, vertical direction between the front side and back side interconnect structures to form the stacked MoM capacitor. By using both front side and back side metallization layers for the formation of the stacked MoM capacitor in the die, area in the front side metallization layers of the die that would otherwise be used as part of the stacked MoM capacitor can be conserved and used for other signal routing in the die. In this manner, as an example, the capacitance density in the die can be maintained or increase while providing sufficient area in the front side metallization layers for signal routing. Fabrication processes that are used to otherwise form metal lines in front side and back side interconnect structures in a die with through vias and/or contacts can be employed to form the stacked MoM capacitor.

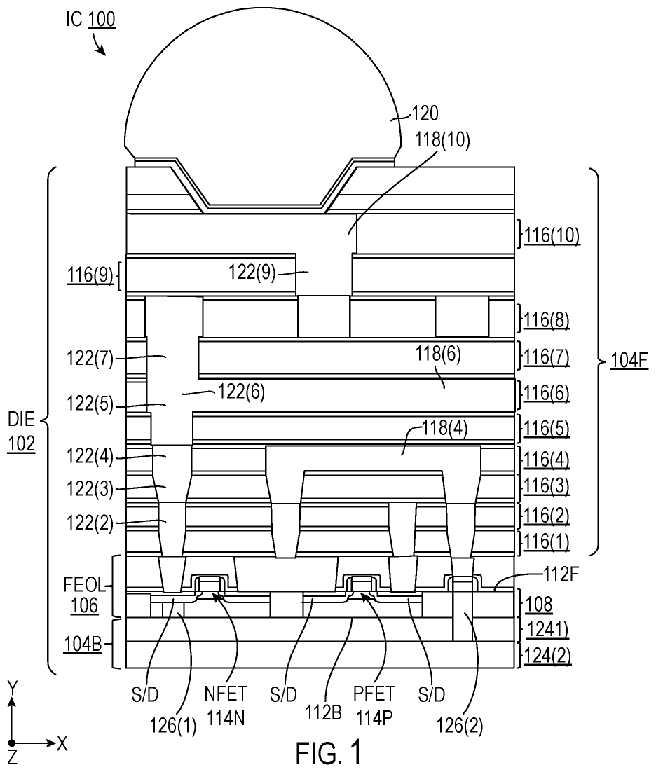

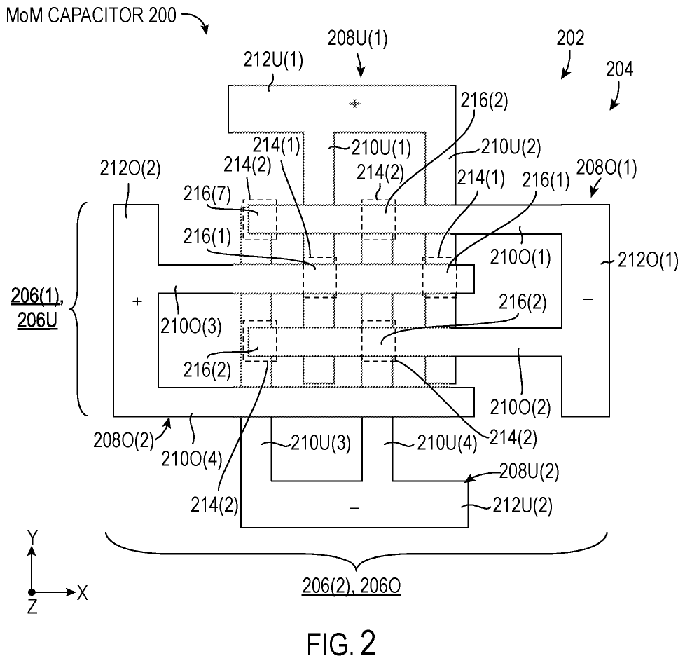

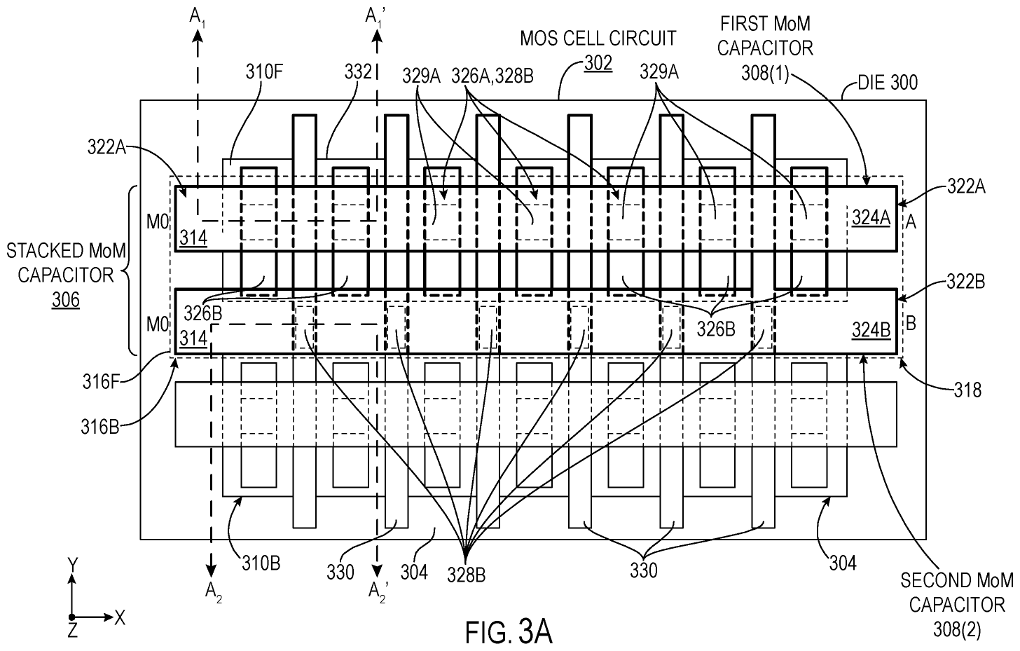

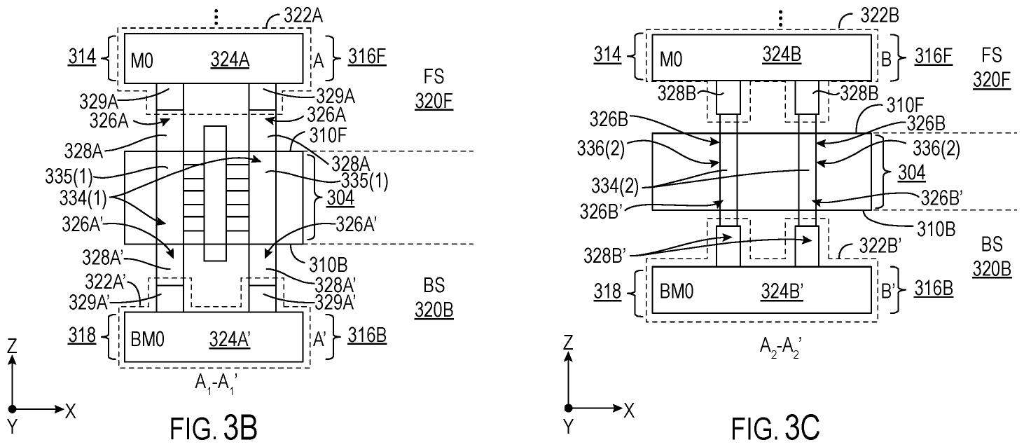

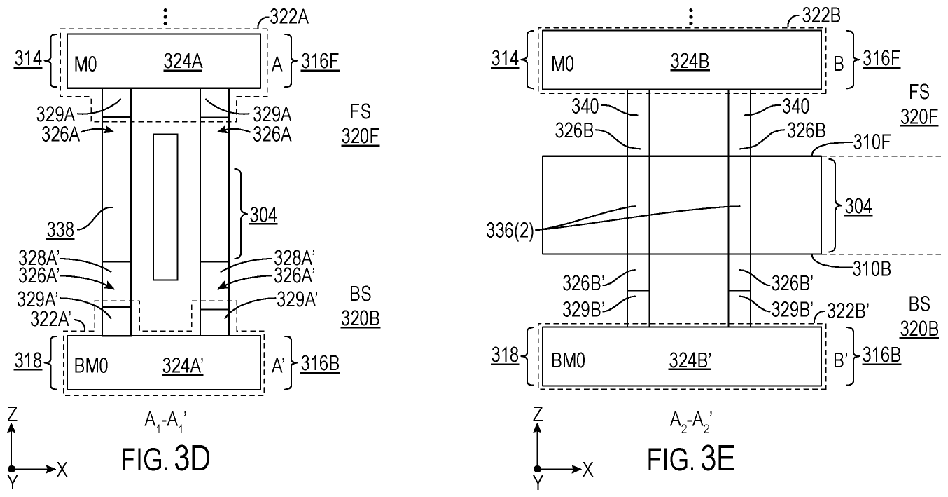

Examples of dies that include a stacked MoM capacitor(s) that includes a first, front side, MoM capacitor formed adjacent to a front side of a semiconductor layer of the die and in front side metallization layers in a front side interconnect structure, coupled to a second, back side MoM capacitor formed adjacent to a back side of the semiconductor layer of the die in back side metallization layers in a back side interconnect structure, start at FIG. 3A discussed below. Before discussing these examples of dies that include such stacked MoM capacitor(s), examples of a die that can include a MoM capacitor are discussed with regard to FIGS. 1 and 2, now discussed below.

In this regard, FIG. 1 is a side view of an integrated circuit (IC) 100 that includes a semiconductor die (“die”) 102 that includes an interconnect structure 104F formed by a back-end-of-line (BEOL) process and disposed on a front-end-of-line (FEOL) structure 106. The FEOL structure 106 includes an active, semiconductor layer 108. The semiconductor layer 108 extends in a first, horizontal direction, which is the X-axis and Y-axis directions as shown in FIG. 1. The semiconductor layer 108 has a first, front side 112F and a second, back side 112B opposite of the first, front side 112F in the second, vertical direction (Z-axis direction). P-type field-effect transistors (FETs) (PFETs) and N-type (FETs) (NFETs) 114P, 114N are formed in the semiconductor layer 108. The interconnect structure 104F, as a front side interconnect structure 104, is disposed adjacent to the front side 112F of the semiconductor layer 108 in the second, vertical direction (Z-axis direction). The front side interconnect structure 104F facilitates signal routing in the die 102 on the front side 112F of the semiconductor layer 108. In this regard, the front side interconnect structure 104F includes a plurality of front side, metallization layers 116(1)-116(10) that each include one or more metal lines 118(1)-118(10) that can provide direct or indirect interconnections between the FETs 114P, 114N and external interconnects 120 (e.g., a solder bump) adjacent to an upper metallization layer 116(10) of the front side interconnect structure 104F. The metal lines 118(1)-118(10) extend in the first, horizontal direction(s) (X- and/or Y-axis directions). The front side interconnect structure 104F also includes vias 122(1)-122(10) disposed through the front side metallization layers 116(1)-116(10) to provide interconnects between metal lines 118(1)-118(10) in adjacent metallization layers 116(1)-116(10).

With continuing reference to FIG. 1, the die 102 also includes a back side interconnect structure 104B that is disposed adjacent to the back side 112B of the semiconductor layer 108 in the second, vertical direction (Z-axis direction). The back side interconnect structure 104B includes a plurality of back side metallization layers 124(1)-124(2) that can provide direct or indirect interconnections between the FETs 114P, 114N and external interconnects 120 (e.g., a solder bump). The back side metallization layers 124(1)-124(2) facilitate signal routing in the die 102 on the back side 112B of the semiconductor layer 108. For example, the back side interconnect structure 104B may facilitate providing a power distribution network (PDN) of a power node(s) and a ground node(s) in the back side metallization layers 124(1)-124(2) to facilitate distributing power to the FETs 114P, 114N and/or to other front side metallization layers 116(1)-116(10) in the front side interconnect structure 104F. The back side interconnect structure 104B includes vias 126(1)-126(2) disposed through the back side metallization layers 124(1)-124(2) to provide interconnects to back side metallization layers 124(1)-124(2). For example, in this example, the NFET 114N is coupled through its source/drain S/D through via 126(1) to the back side metallization layer 124(1). The metal line 118(4) is coupled to the back side metallization layer 124(2) through a coupling of the front side interconnect structure 104F to the back side metallization layer 124(2) through via 126(2).

FIG. 2 is a top view of an exemplary stacked metal-oxide-metal (MoM) capacitor 200 that can be provided in an interconnect structure of a die like the front side interconnect structure 104F in the die 102 in FIG. 1. As shown in FIG. 2, the MoM capacitor 200 is formed in an interconnect structure 202 of a die 204, wherein the interconnect structure 202 includes metal lines in adjacent metallization layers 206(1), 206(2). The adjacent metallization layers 206(1), 206(2) can be adjacent metallization layers among the front side metallization layers 116(1)-116(10) in the front side interconnect structure 104F in the die 102 in FIG. 1. The MoM capacitor 200 is a structure that has interdigitated conductive finger structures formed from metal lines or traces in a metallization layer that extends in a first, horizontal direction for increased capacitance density.

In this example, as shown in FIG. 2, the first metallization layer 206(1) of the MoM capacitor 200 is an underlying metallization layer 206U that is disposed underneath the second metallization layer 206(2) as an overlying metallization layer 206O in the second, vertical direction (Z-axis direction). The underlying metallization layer 206U includes a first underlying conductive finger structure 208U(1) that includes first and second underlying metal lines 210U(1), 210U(2) extending in the third, horizontal direction (Y-axis direction) parallel to each other. The first and second underlying metal lines 210U(1), 210U(2) are coupled together through a first underlying metal line 212U(1) disposed in a first, horizontal direction (X-axis direction). The underlying metallization layer 206U also includes a second underlying conductive finger structure 208U(2) that includes third and fourth underlying metal lines 210U(3), 210U(4) extending in the third, horizontal direction (Y-axis direction) parallel to each other. The third and fourth underlying metal lines 210U(3), 210U(4) are coupled together through a second underlying metal line 212U(2) disposed in the first, horizontal direction (X-axis direction).

With continuing reference to FIG. 2, the first underlying conductive finger structure 208U(1) is interdigitated with the second underlying conductive finger structure 208U(2). In this regard, the first and second underlying metal lines 210U(1), 210U(2) of the first underlying conductive finger structure 208U(1) are interdigitated with the respective third and fourth underlying metal lines 210U(3), 210U(4) of the second underlying conductive finger structure 208U(2). The first underlying metal line 210U(1) is disposed adjacent to and between the third and fourth underlying metal lines 210U(3), 210U(4). The second underlying metal line 210U(2) is disposed adjacent to the fourth underlying metal line 210U(4). The fourth underlying metal line 210U(4) is disposed adjacent to and between the first and second underlying metal lines 210U(1), 210U(2).

Also, as shown in FIG. 2, the overlying metallization layer 206O includes a first overlying conductive finger structure 208O(1) that includes first and second overlying metal lines 210O(1), 210O(2) extending in the third, horizontal direction (Y-axis direction) parallel to each other. The first and second overlying metal lines 210O(1), 210O(2) are coupled together through a first overlying metal line 212O(1) disposed in the first, horizontal direction (X-axis direction). The overlying metallization layer 206O also includes a second overlying conductive finger structure 208O(2) that includes third and fourth overlying metal lines 210O(3), 210O(4) extending in the third, horizontal direction (Y-axis direction) parallel to each other. The third and fourth overlying metal lines 210O(3), 210O(4) are coupled together through a second overlying metal line 212O(2) disposed in the first, horizontal direction (X-axis direction). The first overlying conductive finger structure 208O(1) is interdigitated with the second overlying conductive finger structure 208O(2). In this regard, the first and second overlying metal lines 210O(1), 210O(2) of the first overlying conductive finger structure 208O(1) are interdigitated with the respective third and fourth overlying metal lines 210O(3), 210O(4) of the second overlying conductive finger structure 208O(2). The third overlying metal line 210O(3) is disposed adjacent to and between the first and second overlying metal lines 210O(1), 210O(2). The fourth overlying metal line 210O(4) is disposed adjacent to the second overlying metal line 210O(2). The second overlying metal line 210O(2) is disposed adjacent to and between the third and fourth overlying metal lines 210O(3), 210O(4). As an example, the first underlying conductive finger structure 208U(1) and the second overlying conductive finger structure 208O(2) may be of the same polarity (+), and the second underlying conductive finger structure 208U(2) and the first overlying conductive finger structure 208O(1) may be of a second, different polarity (−).

With continued reference to FIG. 2, the first overlying conductive finger structure 208O(1) intersects the first underlying conductive finger structure 208U(1) in the first and third horizontal directions (X- and Y-axis directions) in a first connection region 214(1). The first overlying conductive finger structure 208O(1) is coupled to the first underlying conductive finger structure 208U(1) in the first connection region 214(1) with vias 216(1). In this example, the third overlying metal line 210O(3) intersects and is coupled to the first and second underlying metal lines 210U(1), 210U(2) in the first, and third horizontal directions (X- and Y-axis directions). The second overlying conductive finger structure 208O(2) intersects the second underlying conductive finger structure 208U(2) in the first and third horizontal directions (X- and Y-axis directions) in a second connection region 214(2). The second overlying conductive finger structure 208O(2) is coupled to the second underlying conductive finger structure 208U(2) in the second connection region 214(2) with vias 216(2). In this example, the first and second overlying metal lines 210O(1), 210O(2) intersect and are coupled to the third and fourth underlying metal lines 210U(3), 210U(4) in the horizontal X- and Y-axis directions.

Even with the ability to integrate the MoM capacitor 200 in FIG. 2 in the front side interconnect structure 104F of the die 102 in FIG. 1, with continuous scaling down of die area, it has become increasingly difficult to provide sufficient area in the layout of the die 102 for passive devices, including MoM capacitors. The front side interconnect structure 104F of the die 102 decreases as the area of the die 102 footprint decreases, thus leaving less area for formation of metal lines 118(1)-118(10) in the front side metallization layers 116(1)-116(10) of the front side interconnect structure 104F to provide necessary signal routing. This in turn consumes additional area in the front side interconnect structure 104F that now becomes available for the formation of passive devices, such as the MoM capacitor 200 in FIG. 2.

In this regard, FIG. 3A is a top view of an exemplary die 300 that includes a cell circuit 302 that includes a semiconductor layer 304 that extends in first and third directions (X-axis and Y-axis directions). The die 300 may be similar to the die 102 in FIG. 1. In this example, the cell circuit 302 can be a metal-oxide semiconductor (MOS) cell circuit includes structures that provide for the formation of MOS circuits. However, as discussed in more detail below, the die 300 in FIG. 3A includes a stacked MoM capacitor 306 that includes a first MoM capacitor 308(1) disposed on a front side 310F of the semiconductor layer 304 of the die 300, and a second MoM capacitor 306(2) disposed on a back side 310B of the semiconductor layer 304 and coupled to the first MoM capacitor 308(1). The first MoM capacitor 308(1) is formed as at least part of a front side metallization layer 314 in a front side interconnect structure 316F formed on or adjacent to the front side 310F of the semiconductor layer 304 in the second, vertical direction (Z-axis direction). In other words, the first MoM capacitor 308(1) is formed either fully or partially from components that are part of the front side interconnect structure 316F in this example. For example, the front side metallization layer 314 may be a metal O(MO) layer in the die directly adjacent to the semiconductor layer 304. The back side 310B of the semiconductor layer 304 is on the opposite side of the front side 310F of the semiconductor layer 304 in the second, vertical direction (Z-axis direction).

In this example, the front side interconnect structure 316F fully contains the first MoM capacitor 308(1), meaning the metal structures forming the first MoM capacitor 308(1) are fully provided (i.e., contained) in the front side interconnect structure 316F. However, in an alternative example, the front side interconnect structure 316F could partially contain the first MoM capacitor 308(1), meaning the metal structures forming the first MoM capacitor 308(1) are partially provided (i.e., contained) in the front side interconnect structure 316F, but other metal structures forming part of the first MoM capacitor 308(1) may be outside of the front side interconnect structure 316F, such as in an adjacent cell circuit or other adjacent structure.

With continuing reference to FIG. 3A, the second MoM capacitor 308(2) is formed as at least part of a back side metallization layer 318 of a back side interconnect structure 316B formed on or adjacent to the back side 310B of the semiconductor layer 304 in the second, vertical direction (Z-axis direction). In other words, the second MoM capacitor 308(2) is formed either fully or partially from components that are part of the back side interconnect structure 316B in this example. Note that because the die 300 is shown in a top view in FIG. 3A, only the first MoM capacitor 308(1) on the front side 310F of the semiconductor layer 304 is shown in FIG. 3A. The back side interconnect structure 316B and the second MoM capacitor 308(2) of the back side interconnect structure 316B is hidden below the first MoM capacitor 308(1) on the back side 310B of the semiconductor layer 304 in the top view of the die 300 in FIG. 3A in this example.

In this example, the back side interconnect structure 316B fully contains the second MoM capacitor 308(2), meaning the metal structures forming the second MoM capacitor 308(2) are fully provided (i.e., contained) in the back side interconnect structure 316B. However, in an alternative example, the back side interconnect structure 316B could partially contain the second MoM capacitor 308(1), meaning the metal structures forming the second MoM capacitor 308(2) are partially provided (i.e., contained) in the back side interconnect structure 316B, but other metal structures forming part of the second MoM capacitor 308(2) may be outside of the back side interconnect structure 316B, such as in an adjacent cell circuit or other adjacent structure.

As discussed in more detail below, in this example, the structures of the cell circuit 302 are advantageously used to form the structures of the first and second MoM capacitors 308(1), 308(2) and to couple them together through the semiconductor layer 304. In this manner, as an example, by providing the stacked MoM capacitor 306 as the first MoM capacitor 308(1) of the front side interconnect structure 316F of the die 300 coupled to the second MoM capacitor 308(2) of the back side interconnect structure 316B of the die 300, the capacitance density in the die 300 can be maintained or increased while providing sufficient area in the front side interconnect structure 316F for signal routing. The back side interconnect structure 316B is utilized to provide the second MoM capacitor 308(2) as part of the stacked MoM capacitor 306 to conserve area in the front side interconnect structure 316F. Also, fabrication processes that are used to otherwise form metal lines in front side and back side interconnect structures in a die with through vias and/or contacts, can be employed to form the stacked MoM capacitor 306 in the die 300. Also, as another example, if a power distribution network (PDN) is provided in the back side interconnect structure 316B of the die 300, the second MoM capacitor 308(2) can be more closely located to the node of the PDN to lower coupling resistance and inductance between the stacked MoM capacitor 306 and the PDN for improved decoupling capacitance and reduced current-resistance (IR) drop.

FIGS. 3B and 3C are cross-sectional side views of the die 300 in FIG. 3A to provide more illustration of the exemplary components of the first MoM capacitor 308(1) and the second MoM capacitor 308(2) of the stacked MoM capacitor 306 formed in the die 300 and its cell circuit 302. FIG. 3B illustrates a cross-sectional view across the A1-A1′ cross-section line of the die 300 as shown in the top view of the die 300 in FIG. 3A. FIG. 3C illustrates a cross-sectional view across the A2-A2′ cross-section line of the die 300 as shown in the top view of the die 300 in FIG. 3A. The front side 320F and back side 320B of the die 300 are shown in FIGS. 3B and 3C. The front side 320F of the die 300 is the area from the front side 310F of the semiconductor layer 304 in a direction away from the semiconductor layer 304 in the second, vertical direction (Z-axis direction). The back side 320B of the die 300 is the area from the back side 310B of the semiconductor layer 304 in a direction away from the semiconductor layer 304 in the second, vertical direction (Z-axis direction).

FIG. 3B illustrates a first conductive finger structure 322A of the first MoM capacitor 308(1) on the front side 320F of the die 300, and a second conductive finger structure 322A′ of the second MoM capacitor 308(2) on the back side 320F of the die 300. FIG. 3C illustrates a third conductive finger structure 322B of the first MoM capacitor 308(1) on the front side 320F of the die 300, and a fourth conductive finger structure 322B′ of the second MoM capacitor 308(2) on the back side 320F of the die 300. As shown in FIG. 3A, the first conductive finger structure 322A of the first MoM capacitor 308(1) is interdigitated with the third conductive finger structure 322B of the first MoM capacitor 308(1). Although hidden from the top view of the die 300 in FIG. 3A, like the first MoM capacitor 308(1), the second conductive finger structure 322A′ of the second MoM capacitor 308(2) is interdigitated with the fourth conductive finger structure 322B′ of the second MoM capacitor 308(2). This forms the stacked MoM capacitor 306 formed by the first MoM capacitor 308(1) on the front side 320F of the die 300 and the second MoM capacitor 308(2) on the back side 320B of the die 300.

In this example, as shown in FIGS. 3A and 3B, the first conductive finger structure 322A of the first MoM capacitor 308(1) is formed by a first metal line 324A extending in the first, horizontal direction (X-axis direction) in the front side metallization layer 314. The first metal line 324A is coupled to a plurality of first finger metal lines 326A orthogonally extending in the third, horizontal direction (Y-axis direction) also in the front side metallization layer 314. In this example, the first finger metal lines 326A are front side, first metal contacts 328A formed adjacent to the semiconductor layer 304 to couple the first MoM capacitor 308(1) to the second MoM capacitor 308(2). The first metal line 324A is coupled to the front side, first metal contacts 328A as the first finger metal lines 326A by vias 329A (e.g., middle-of-line (MOL vias)).

Also in this example, as shown in FIGS. 3A and 3C, the second conductive finger structure 322B of the first MoM capacitor 308(1) is formed by a second metal line 324B extending in the first, horizontal direction (X-axis direction) in the front side metallization layer 314. The second metal line 324B is coupled to a plurality of second finger metal lines 326B orthogonally extending in the third, horizontal direction (Y-axis direction) also in the front side metallization layer 314. In this example, the second finger metal lines 326B include gates 330 as second metal lines that are coupled to front side, second metal gate contacts 328B (“second gate contacts 328B”) formed adjacent to the semiconductor layer 304 to couple the second metal line 324B to the gates 330. The gates 330 provide a second conductive structure 334(2) to couple the first MoM capacitor 308(1) to the second MoM capacitor 308(2), as shown in FIG. 3A. In this regard, the first and second conductive finger structures 322A, 322B of the first MoM capacitor 308(1) and their finger metal lines 326A, 326B are interdigitated with each other in the front side metallization layer 314. The first MoM capacitor 308(1) has first and second conductive finger structures 322A, 322B similar to the first and second overlying conductive finger structures 208O(1), 208O(2) in the MoM capacitor 200 in FIG. 2. In this manner, structures that are fabricated in cell circuits can be used to form the first MoM capacitor 308(1) in the front side 320F of the die 300.

Also in this example, as shown in FIG. 3B, the third conductive finger structure 322A′ of the second MoM capacitor 308(2) is formed by a third metal line 324A′ extending in the first, horizontal direction (X-axis direction) in the back side metallization layer 318. The third metal line 324A′ is coupled to a plurality of third finger metal lines 326A′ orthogonally extending in the third, horizontal direction (Y-axis direction) also in the back side metallization layer 318. In this example, the third finger metal lines 326A′ are back side, third metal contacts 328A′ formed adjacent to the semiconductor layer 304 to couple the first MoM capacitor 308(1) to the second MoM capacitor 308(2). The back side, third metal contacts 328A′ are coupled to the third metal line 324A′ by vias 329A′ (e.g., MOL vias).

Also in this example, as shown in FIGS. 3A and 3C, the fourth conductive finger structure 322B′ of the second MoM capacitor 308(2) is formed by a fourth metal line 324B′ extending in the first, horizontal direction (X-axis direction) in the back side metallization layer 318. The fourth metal line 324B′ is coupled to a plurality of fourth finger metal lines 326B′ orthogonally extending in the third, horizontal direction (Y-axis direction) also in the back side metallization layer 318. In this example, the fourth finger metal lines 326B′ include the gates 330 as fourth metal lines that are coupled to the back side, fourth metal gate contacts 328B′ (“fourth gate contacts 328B′”) formed adjacent to the semiconductor layer 304 to couple the fourth metal line 324B′ to the gates 330. The gates 330 provide a second conductive structure 334(2) to couple the first MoM capacitor 308(1) to the second MoM capacitor 308(2), as shown in FIG. 3A. In this regard, the third and fourth conductive finger structures 322A′, 322B′ of the second MoM capacitor 308(2) and their finger metal lines 326A′, 326B′ are interdigitated with each other as part of the back side metallization layer 318. The second MoM capacitor 308(2) has third and fourth conductive finger structures 322A′, 322B′ similar to the first and second underlying conductive finger structures 208U(1), 208U(2) in the MoM capacitor 200 in FIG. 2. In this manner, structures that are fabricated in cell circuits can be used to form the second MoM capacitor 308(2) on the back side 320B of the die 300.

With continuing reference to FIG. 3A, in this example, the first metal line 324A of the first MoM capacitor 308(1) and the third metal line 324A′ of the second MoM capacitor 308(2) partially intersect a diffusion region 332 of the cell circuit 302 in the second, vertical direction (Z-axis direction). For example, the diffusion region 332 could be an N-type diffusion region where PFETs are formed, or a P-type diffusion region where NFETs are formed. Also in this example, the second metal line 324B of the first MoM capacitor 308(1) and the fourth metal line 324B′ of the second MoM capacitor 308(2) do not intersect the diffusion region 332 of the cell circuit 302 in the second, vertical direction (Z-axis direction), because the second metal line 324B and fourth metal line 324B′ are formed outside the diffusion region 332 in an area where a gate cut in the gates 330 is present. Also, in this example, the second and fourth gate contacts 328B, 328B′ do not intersect the diffusion region 332.

With reference to FIGS. 3A and 3B, providing the stacked MoM capacitor 306 in the cell circuit 302 provides some methods in which the first and second MoM capacitors 308(1), 338(2) on the respective front and back sides 320F, 320B of the die 300 can be coupled together. For example, as shown in FIG. 3B, the first and third metal contacts 328A, 328A′ of the respective first and third conductive finger structures 322A, 322A′ of the first and second MoM capacitors 308(1), 308(2) are coupled through first conductive structures 334(1) that extend in the second, vertical direction (Z-axis direction). The first conductive structures 334(1) couple the front side, first metal contacts 328A of the first MoM capacitor 308(1) to the back side, third metal contacts 328A′ of the second MoM capacitor 308(2). In this example, the first conductive structures 334(1) include first conductive structures 334(1) in the diffusion region 332 that would be like that formed for a FET. As an example, the first conductive structures 334(1) could be epitaxially grown as epitaxial layers 335(1) like would be grown to form a source and/or drain if the first conductive structures 334(1) were formed as part of a FET. In this manner, fabrication methods used to fabricate devices in a cell circuit 302 can be utilized to couple the first MoM capacitor 308(1) to the second MoM capacitor 308(2). Also in this example, by forming the first conductive structures 334(1) as epitaxial layers 335(1), the first conductive structures 334(1) are semiconductor capacitors that are formed by each epitaxial layer 335(1) adjacent to a gate 330 of the plurality of gates 330 to add more capacitance to the stacked MoM capacitor 306.

With continuing reference to FIGS. 3A and 3C, the second and fourth metal contacts 328B, 328B′ of the respective second and fourth conductive finger structures 322B, 322B′ of the first and second MoM capacitors 308(1), 308(2) are coupled through second conductive structures 334(2) that extend in the second, vertical direction (Z-axis direction). The second conductive structures 334(2) couple the front side, second metal contacts 328B of the first MoM capacitor 308(1) to the back side, fourth metal contacts 328B′ of the second MoM capacitor 308(2). In this example, the second conductive structures 334(2) include vias 336(2) coupled to the second and fourth gate contacts 328B, 328B′. In this manner, fabrication methods used to fabricate devices in a cell circuit 302 can be utilized to couple the first MoM capacitor 308(1) to the second MoM capacitor 308(2).

There are other methods of providing the first and second conductive structures 334(1), 334(2) to couple the first and third conductive finger structures 322A, 322A′ and the second and fourth conductive finger structures 322B, 322B′ together of the first and second MoM capacitors 308(1), 308(2) of the stacked MoM capacitor 306.

For example, FIG. 3D illustrates an alternative side view across the cross-sectional lines A1-A1′ of the cell circuit 302 in FIG. 3A, but illustrating one of first conductive structures 334(1) coupling the first conductive finger structure 322A to the third conductive finger structure 322A′ as a fixed metal contact 338 that is coupled to the first and third metal contacts 328A, 328A′. Note that other first conductive structures 334(1) could also be provided as the fixed metal contact 328.

FIG. 3E illustrates another alternative side view across the cross-sectional lines A2-A2′ of the cell circuit 302 in FIG. 3A, but illustrating the second conductive structures 334(2) coupling the second conductive finger structure 322B to the fourth conductive finger structure 322B′ as vias 340 directly coupled to the second metal line 324B. For example, the vias 340 could be through-silicon vias (TSVs) that are formed through the semiconductor layer 304. Note that the vias 340 could also be formed to be directly coupled to the fourth metal line 324B′, but in this example, the vias 340 are coupled to the fourth metal line 324B′ through the back side vias 329B′. The back side vias 329B′ can be provided in case the vias 340 are nano TSVs (nTSVs). Direct TSVs like the vias 340 in FIG. 3E could also be used to couple the first metal line 324A to the third metal line 324A′ for the first MoM capacitor 308(1) shown in FIG. 3D as another example.

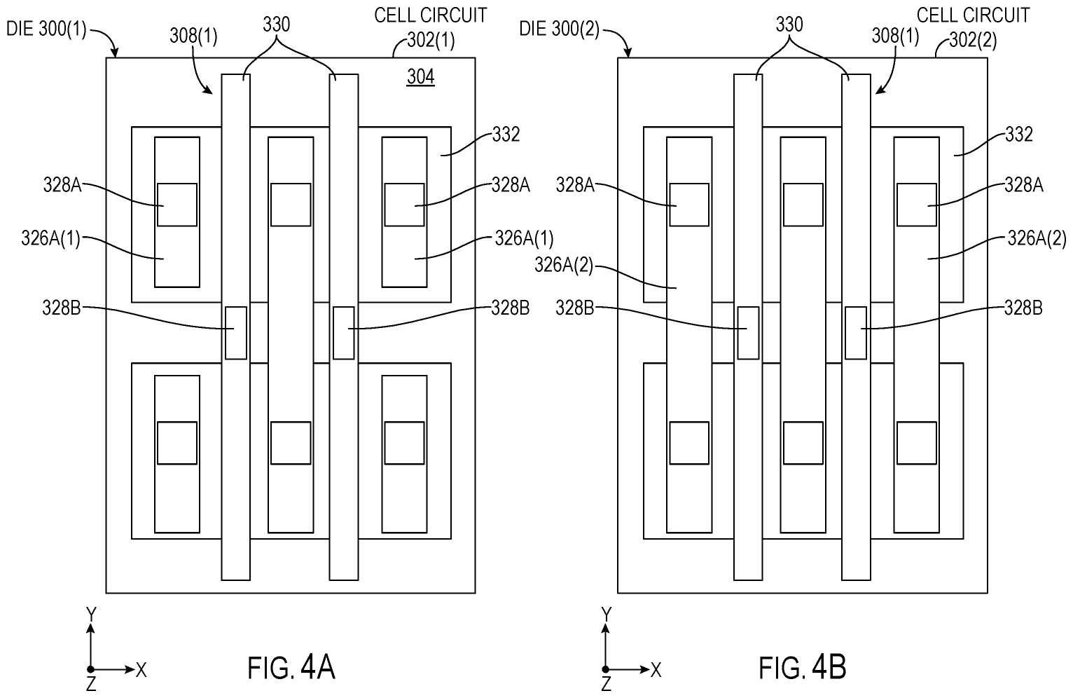

FIGS. 4A and 4B are top views illustrating exemplary relaxed and tighter process margins that can be provided in the die 300 in FIGS. 3A and 3B for coupling the first, front side, MoM capacitor 308(1) of the stacked MoM capacitor 306 to the second, back side, MoM capacitor 308(2).

FIG. 4A illustrates an alternative die 300(1) that is like the die 300 in FIGS. 3A-3D that includes a cell circuit 302(1) like the cell circuit 302 in the die 300. Common elements between the die 300(1) in FIG. 4A and the die 300 in FIGS. 3A-3D are shown with common element numbers. As shown in the die 300(1) in FIG. 4A, the process margin is relaxed in the cell circuit 302(1) by first finger metal lines 326A(1) of the first MoM capacitor 308(1) not extending outside of the diffusion region 332. This is the configuration of the cell circuit 302 in FIG. 3A as an example. This provides more process margin and room to form the front side, second gate contacts 328B used to form the second finger metal lines 326B of the first MoM capacitor 308(1) that are outside of the diffusion region 332. The front side, second gate contacts 328B of the second finger metal lines 326B are not adjacent to the front side, first metal contacts 328A of the first finger metal lines 326A(1) in the first, horizontal direction (X-axis direction). Note that the same process margin exists between the third finger metal lines 326A′ and fourth finger metal lines 326B′ of the second MoM capacitor 408(2), but such is hidden in the top view in FIG. 4A.

FIG. 4B illustrates another alternative die 300(2) that is like the die 300 in FIGS. 3A-3D that includes a cell circuit 302(2) like the cell circuit 302 in the die 300. Common elements between the die 300(2) in FIG. 4B and the die 300 in FIGS. 3A-3D are shown with common element numbers. As shown in the die 300(2) in FIG. 4B, the process margin is tighter in the cell circuit 302(2) than in the cell circuit 302(1) in FIG. 4A. The first finger metal lines 326A(2) of the first MoM capacitor 308(1) extend outside of the diffusion region 332 and adjacent to the front side, second gate contacts 328B coupled to the second finger metal lines 326B in the first, horizontal direction (X-axis direction). Note that the same process margin exists between the third finger metal lines 326A′ and fourth finger metal lines 326B′ of the second MoM capacitor 308(2), but such is hidden in the top view in FIG. 4A.

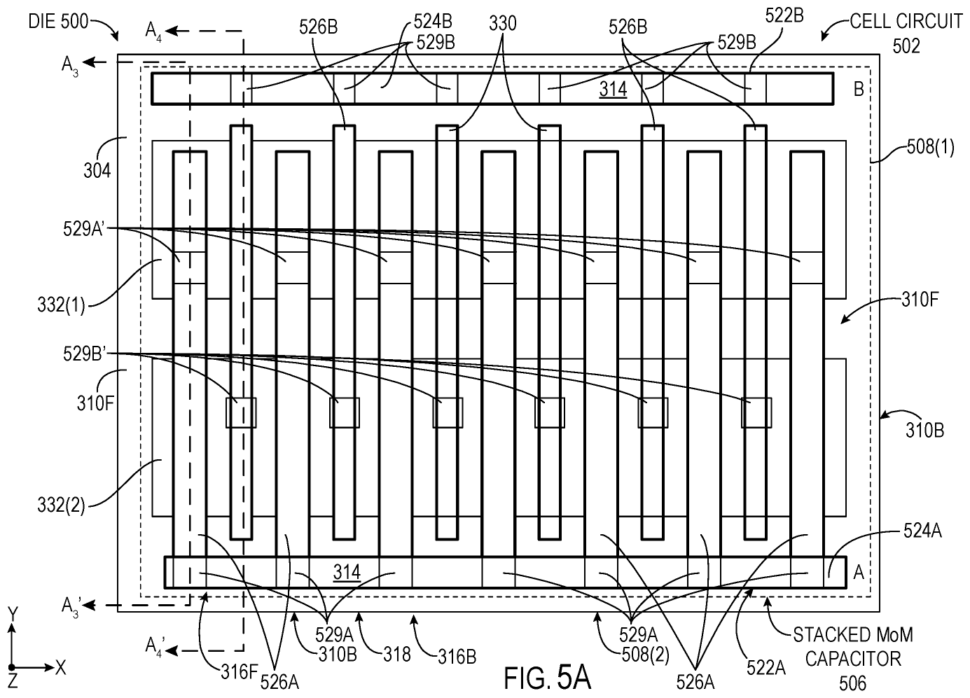

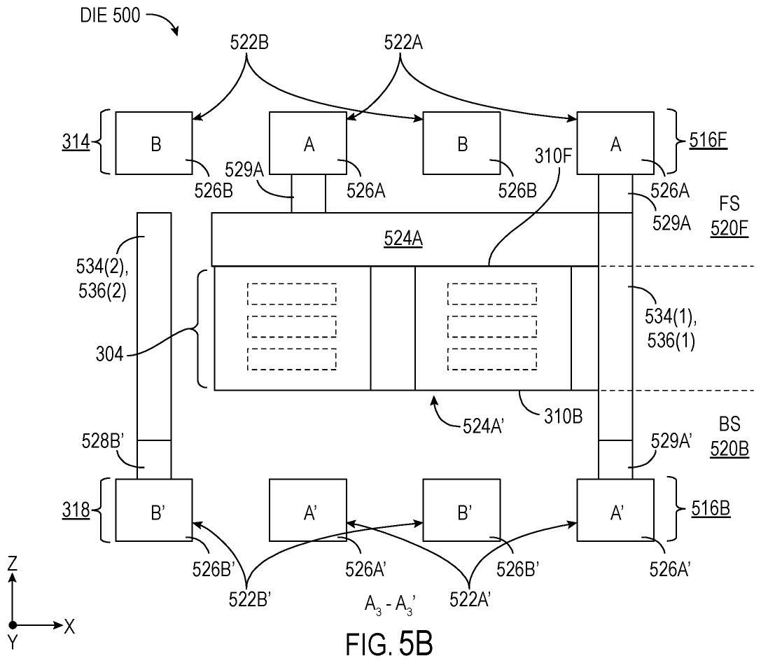

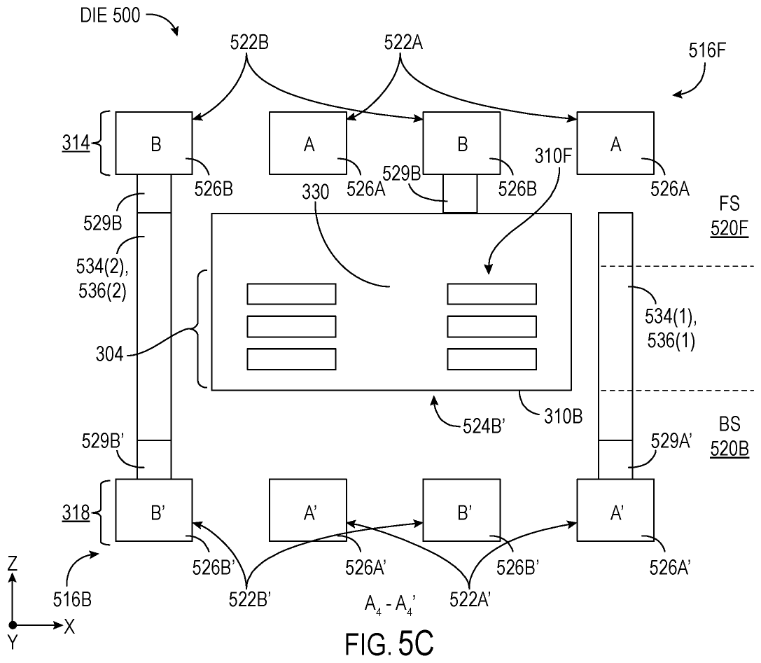

FIG. 5A is a top view of another exemplary die 500 that includes another stacked MoM capacitor 506 similar to the stacked MoM capacitor 306 in FIGS. 3A-3D, but that includes metal lines of the conductive finger structures outside of the diffusion region 332. Common elements between the die 500 in FIG. 5A and the die 300 in FIGS. 3A-3D are shown with common element numbers.

The die 500 in FIG. 5A includes a stacked MoM capacitor 506 that includes a first MoM capacitor 508(1) disposed on the front side 310F of the semiconductor layer 304 of the die 500, and a second MoM capacitor 508(2) disposed on the back side 310B of the semiconductor layer 304 and coupled to the first MoM capacitor 508(1). The first MoM capacitor 508(1) is formed as part of the front side metallization layer 314 in the front side interconnect structure 316F formed on or adjacent to the front side 310F of the semiconductor layer 304 in the second, vertical direction (Z-axis direction). The back side 310B of the semiconductor layer 304 is on the opposite side of the front side 310F of the semiconductor layer 304 in the second, vertical direction (Z-axis direction). The second MoM capacitor 308(2) is formed as part of the back side metallization layer 318 of the back side interconnect structure 316B formed on or adjacent to the back side 310B of the semiconductor layer 304 in the second, vertical direction (Z-axis direction). Note that because the die 500 is shown in a top view in FIG. 5A, only the first MoM capacitor 508(1) on the front side 310F of the semiconductor layer 304 is shown in FIG. 5A. The back side interconnect structure 316B and the second MoM capacitor 508(2) as part of the back side interconnect structure 316B is hidden below the first MoM capacitor 508(1) on the back side 310B of the semiconductor layer 304 in the top view of the die 500 in FIG. 5A in this example.

FIGS. 5B and 5C are cross-sectional side views of the die 500 in FIG. 5A to provide more illustration of the exemplary components of the first MoM capacitor 508(1) and second MoM capacitor 508(2) of the stacked MoM capacitor 506 formed in the die 500 and its cell circuit 502. The cell circuit 502 may be a MOS cell circuit. FIG. 5B illustrates a cross-sectional view across the A3-A3′ cross-section line of the die 500 as shown in the top view of the die 500 in FIG. 5A. FIG. 5C illustrates a cross-sectional view across the A4-A4′ cross-section line of the die 500 as shown in the top view of the die 500 in FIG. 5A. The front side 520F and back side 520B of the die 500 are shown in FIGS. 5B and 5C. The front side 520F of the die 500 is the area from the front side 310F of the semiconductor layer 304 in a direction away from the semiconductor layer 304 in the second, vertical direction (Z-axis direction). The back side 520B of the die 500 is the area from the back side 310B of the semiconductor layer 304 in a direction away from the semiconductor layer 304 in the second, vertical direction (Z-axis direction).

FIGS. 5A and 5B illustrate a first conductive finger structure 522A of the first MoM capacitor 508(1) on the front side 520F of the die 500, and a second conductive finger structure 522A′ of the second MoM capacitor 508(2) on the back side 520B of the die 500. FIGS. 5A and 5C illustrate a third conductive finger structure 522B of the first MoM capacitor 508(1) on the front side 520F of the die 500, and a fourth conductive finger structure 522B′ of the second MoM capacitor 508(2) on the back side 520B of the die 500. As shown in FIG. 5A, the first conductive finger structure 522A of the first MoM capacitor 508(1) is interdigitated with the second conductive finger structure 522B of the first MoM capacitor 508(1). Although hidden from the top view of the die 500 in FIG. 5A, like the first MoM capacitor 508(1), the third conductive finger structure 522A′ of the second MoM capacitor 508(2) is interdigitated with the fourth conductive finger structure 522B′ of the second MoM capacitor 508(2). This forms the stacked MoM capacitor 506 formed by the first MoM capacitor 508(1) on the front side 520F of the die 500 and the second MoM capacitor 508(2) on the back side 520B of the die 500.

In this example, as shown in FIGS. 5A and 5B, the first conductive finger structure 522A of the first MoM capacitor 508(1) is formed by a first metal line 524A extending in the first, horizontal direction (X-axis direction) in the front side metallization layer 314. The first metal line 524A is coupled to a plurality of first finger metal lines 526A orthogonally extending in the third, horizontal direction (Y-axis direction) also in the front side metallization layer 314. The first finger metal lines 526A are coupled to the first metal line 524A through front side vias 529A. In this example, the first metal line 524A is outside of the diffusion regions 332(1), 332(2), which may be P-type and/or N-type diffusion regions. For example, the first metal line 524A may be designated as a metal line to distribute power as part of a PDN. In this example, the first finger metal lines 526A are first metal lines formed adjacent to the semiconductor layer 304.

Also in this example, as shown in FIGS. 5A and 5C, the second conductive finger structure 522B of the first MoM capacitor 508(1) is formed by a second metal line 524B extending in the first, horizontal direction (X-axis direction) in the front side metallization layer 314. The second metal line 524B is coupled to a plurality of second finger metal lines 526B orthogonally extending in the third, horizontal direction (Y-axis direction) also in the front side metallization layer 314. The second finger metal lines 526B are coupled to the second metal line 524B through front side vias 529B. In this example, the second metal line 524B is also outside of the diffusion regions 332(1), 332(2). For example, the second metal line 524B may be designated as a metal line to distribute power as part of a PDN. In this example, the second finger metal lines 526B include the gates 330 as second metal lines formed adjacent to the semiconductor layer 304. In this regard, the first and second conductive finger structures 522A, 522B of the first MoM capacitor 508(1) and their finger metal lines 526A, 526B are interdigitated with each other in the front side metallization layer 314. The first MoM capacitor 508(1) has first and second conductive finger structures 522A, 522B similar to the first and second overlying conductive finger structures 208O(1), 208O(2) in the MoM capacitor 200 in FIG. 2. In this manner, structures that are fabricated in cell circuits can be used to form the first MoM capacitor 508(1) in the front side 520F of the die 500.

Also in this example, as shown in FIG. 5B, the third conductive finger structure 522A′ of the second MoM capacitor 508(2) is formed by a third metal line 524A′ (shown as hidden in the cross-sectional view in FIG. 5B) extending in the first, horizontal direction (X-axis direction) in the back side metallization layer 318. The third metal line 524A′ is coupled to a plurality of third finger metal lines 526A′ coupled to the third metal line 524A′ and orthogonally extending in the third, horizontal direction (Y-axis direction) also in the back side metallization layer 318. In this example, the third finger metal lines 526A′ are third metal lines formed adjacent to the semiconductor layer 304. The third metal line 524A′ is coupled to the third finger metal lines 526A′ through vias 529A′ in this example.

Also in this example, as shown in FIGS. 5A and 5C, the fourth conductive finger structure 522B′ of the second MoM capacitor 508(2) is formed by a fourth metal line 524B′ (shown as hidden in the cross-sectional view in FIG. 5C) extending in the first, horizontal direction (X-axis direction) in the back side metallization layer 318. The fourth metal line 524B′ is coupled to a plurality of fourth finger metal lines 526B′ orthogonally extending in the third, horizontal direction (Y-axis direction) also in the back side metallization layer 318. In this example, the fourth metal line 524B′ is coupled to the fourth finger metal lines 526B′ through vias 529B′. Also in this example, the fourth finger metal lines 526B′ include the gates 330 as fourth metal lines formed adjacent to the semiconductor layer 304. In this regard, the third and fourth conductive finger structures 522A′, 522B′ of the second MoM capacitor 508(2) and their finger metal lines 526A′, 526B′ are interdigitated with each other in the back side metallization layer 318. The second MoM capacitor 508(2) has third and fourth conductive finger structures 522A′, 522B′ similar to the first and second underlying conductive finger structures 208U(1), 208U(2) of the MoM capacitor 200 in FIG. 2. In this manner, structures that are fabricated in cell circuits can be used to form the second MoM capacitor 508(2) on the back side 520B of the die 500.

With continuing reference to FIG. 5A, in this example, the first metal line 524A of the first MoM capacitor 508(1) and the third metal line 524A′ of the second MoM capacitor 508(2) do not intersect the diffusion regions 332(1), 332(2) of the cell circuit 502 in the second, vertical direction (Z-axis direction). The diffusion regions 332(1), 332(2) could be an N-type diffusion region where PFETs are formed, or a P-type diffusion region where NFETs are formed. Also in this example, the second metal line 524B of the first MoM capacitor 508(1) and the fourth metal line 524B′ of the second MoM capacitor 308(2) do not intersect the diffusion regions 332(1), 332(2) of the cell circuit 502 in the second, vertical direction (Z-axis direction).

With reference to FIGS. 5A-5C, providing the stacked MoM circuit 506 in the cell circuit 502 provides some methods in which the first and second MOM capacitors 508(1), 508(2) on the respective front and back sides 520F, 520B of the die 500 can be coupled together. For example, as shown in FIG. 5B, first and third metal contacts 528A, 528A′ of the respective first and third conductive finger structures 522A, 522A′ of the first and second MoM capacitors 508(1), 508(2) are coupled through first conductive structures 534(1) that extend in the second, vertical direction (Z-axis direction). The first and third metal contacts 528A, 528A′ are coupled to the respective first and third metal lines 524A, 524A′. The first conductive structures 534(1) couple the first metal contacts 528A of the first MoM capacitor 508(1) to the third metal contacts 528A′ of the second MoM capacitor 508(2) to couple the first MoM capacitor 508(1) to the second MoM capacitor 508(1). In this example, the first conductive structures 534(1) can include deep vias 536(1) (e.g., a bar via) coupled to the first and third metal contacts 528A, 528A′. In this manner, fabrication methods used to fabricate devices in a cell circuit 502 can be utilized to couple the first MoM capacitor 508(1) to the second MoM capacitor 508(2).

With continuing reference to FIGS. 5A-5C, second and fourth metal contacts 528B, 528B′ of the respective second and fourth conductive finger structures 522B, 522B′ of the first and second MoM capacitors 508(1), 508(2) are coupled through second conductive structures 534(2) that extend in the second, vertical direction (Z-axis direction). For example, the second and fourth metal contacts 528B, 528B′ may be gate contacts that are coupled to the gates 330 as the second and fourth metal lines 524B, 524B′. In this manner, the second conductive structures 534(2) couple the second metal contacts 528B of the first MoM capacitor 508(1) to the fourth metal contacts 528B′ of the second MoM capacitor 508(2) to couple the first MoM capacitor 508(1) to the second MoM capacitor 508(1). In this example, the second conductive structures 534(2) include deep vias 536(2) (e.g., a bar via) coupled to the second and fourth metal, gate contacts 528B, 528B′. In this manner, fabrication methods used to fabricate devices in a cell circuit 502 can be utilized to couple the first MoM capacitor 508(2) to the second MoM capacitor 508(2).

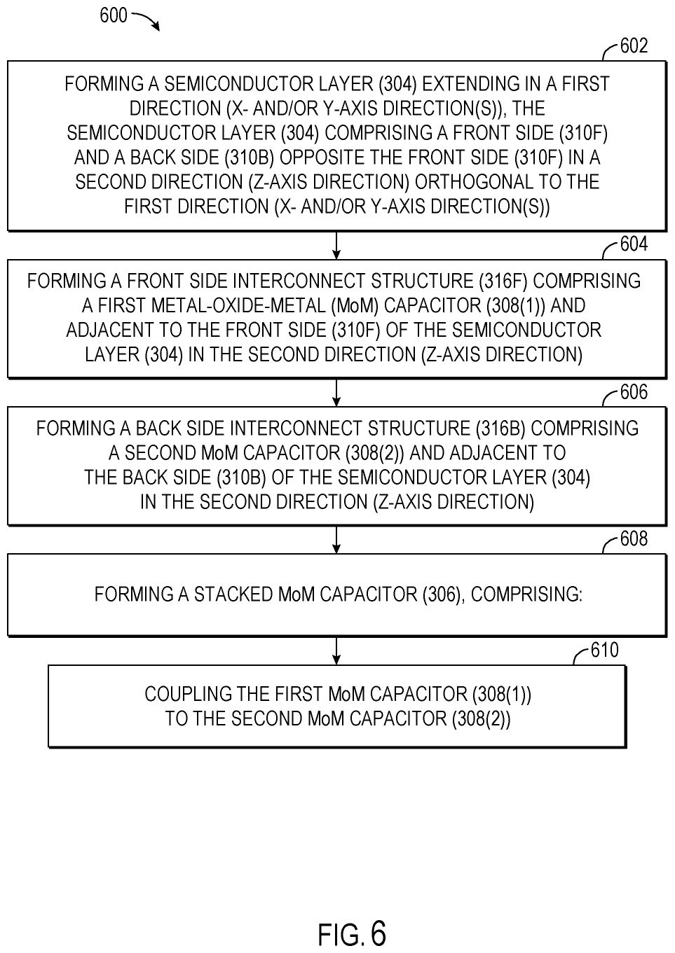

A die that includes a stacked MoM capacitor(s) that includes a first, front side, MoM capacitor formed on a front side of a semiconductor layer of the die and in front side metallization layers in a front side interconnect structure, coupled to a second, back side MoM capacitor formed on a back side of the semiconductor layer of the die in back side metallization layers in a back side interconnect structure, including, but not limited to, the dies 300, 300(1), 300(2), 500 and the stacked MoM capacitors 306, 506 in FIGS. 3A-5C can be fabricated according to a fabrication process. In this regard, FIG. 6 is a flowchart illustrating an exemplary fabrication process 600 of fabricating a die with a stacked MoM capacitor with a first, front side MoM capacitor coupled to a second, back side MoM capacitor, including, but not limited to, the dies 300, 300(1), 300(2), 500 and the stacked MoM capacitors 306, 506 in FIGS. 3A-5C. The fabrication process 600 in FIG. 6 is discussed in reference to the dies 300, 300(1), 300(2), 500 and stacked MOM capacitors 306, 506 in FIGS. 3A-5C, but such is not limiting and could be used to fabricate another die with a stacked MoM capacitor with a first, front side MoM capacitor coupled to a second, back side MoM capacitor, including, but not limited to, the die 500 and stacked MoM capacitor 506 in FIGS. 5A-5C.

In this regard, as shown in FIG. 6, the fabrication process 600 of fabricating the die 300 that includes the stacked MoM capacitor 306 includes forming a semiconductor layer 304 extending in a first direction (X- and/or Y-axis direction(s)), the semiconductor layer 304 comprising a front side 310F and a back side 310B opposite the front side 310F in a second direction (Z-axis direction) orthogonal to the first direction (X- and/or Y-axis direction(s)) (block 602 in FIG. 6). The fabrication process 600 of fabricating the die 300 also includes forming a front side interconnect structure 316F comprising the first MoM capacitor 308(1) and adjacent to the front side 310F of the semiconductor layer 304 in the second direction (Z-axis direction) (block 604 in FIG. 6). The fabrication process 600 of fabricating the die 300 also includes forming a back side interconnect structure 316B comprising the second MOM capacitor 308(2) and adjacent to the back side 310B of the semiconductor layer 304 in the second direction (Z-axis direction) (block 606 in FIG. 6). The fabrication process 600 of fabricating the die 300 also includes forming a stacked MoM capacitor 306(block 608 in FIG. 6). Forming the stacked MoM capacitor 306 comprises coupling the first MoM capacitor 308(1) to the second MoM capacitor 308(2) (block 610 in FIG. 6).

A die that includes a stacked MoM capacitor(s) that includes a first, front side, MoM capacitor formed on a front side of a semiconductor layer of the die and in front side metallization layers in a front side interconnect structure, coupled to a second, back side MoM capacitor formed on a back side of the semiconductor layer of the die in back side metallization layers in a back side interconnect structure including, but not limited to, the dies 300, 300(1), 300(2), 500 and stacked MoM capacitors 306, 506 in FIGS. 3A-5C, can be fabricated in other fabrication processes.

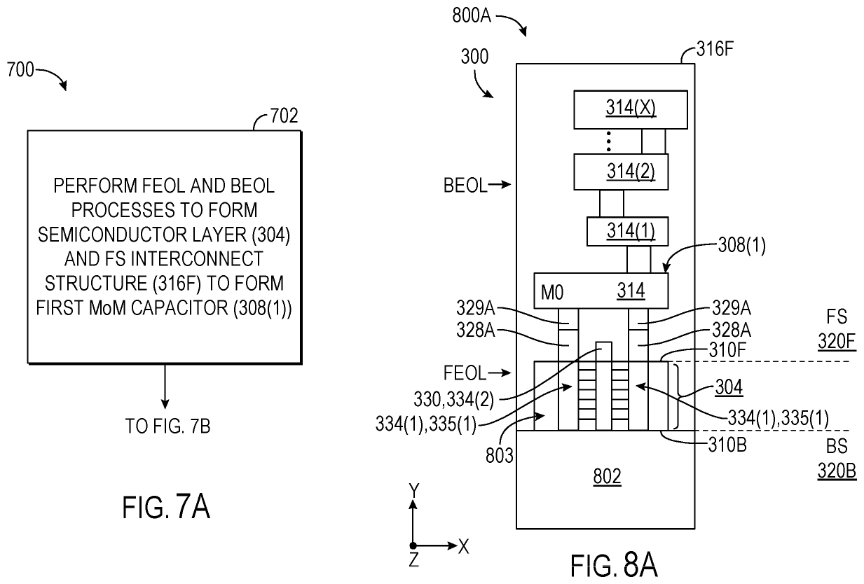

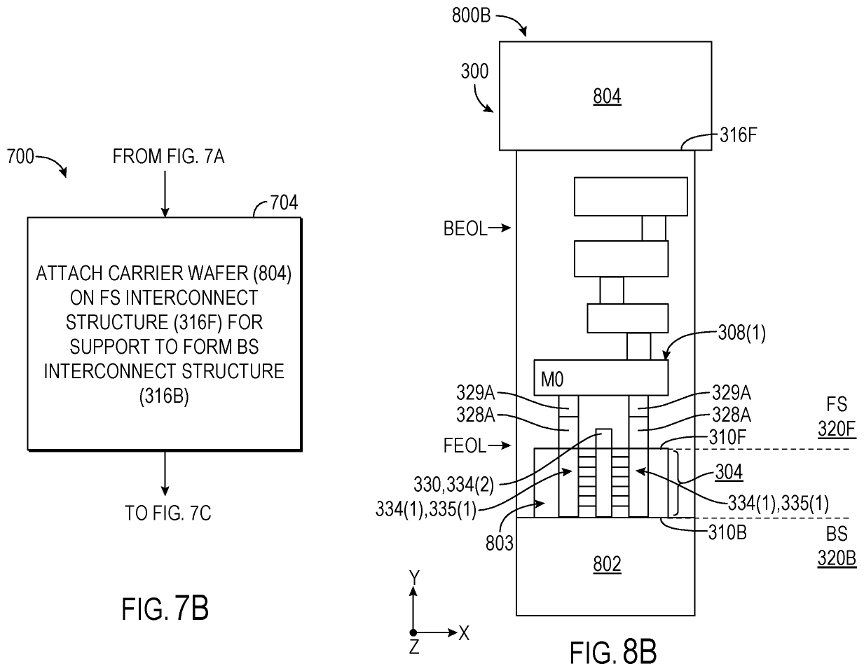

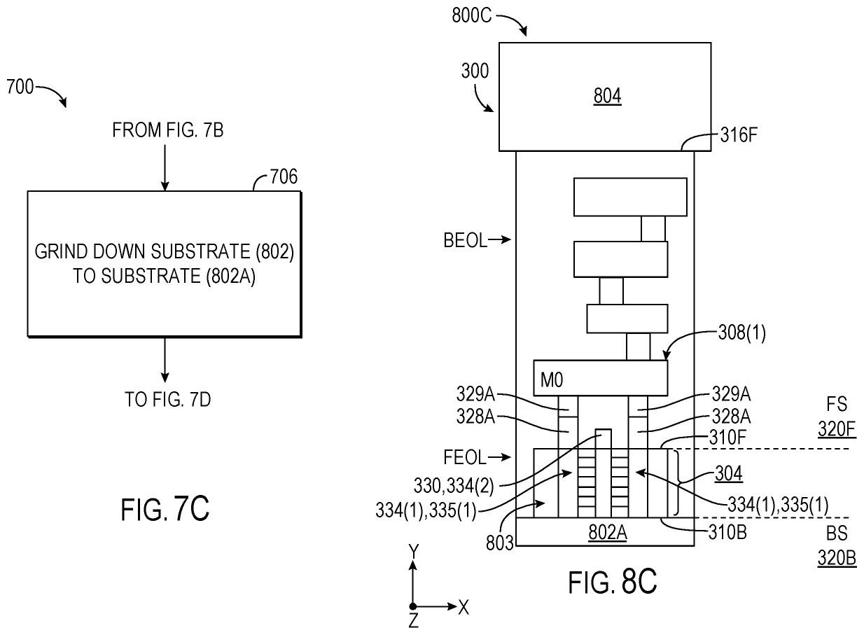

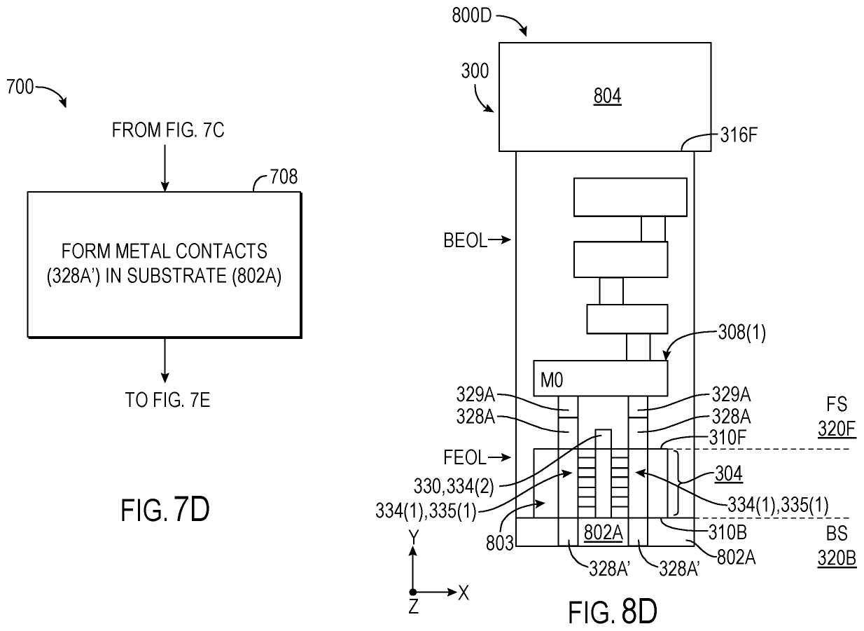

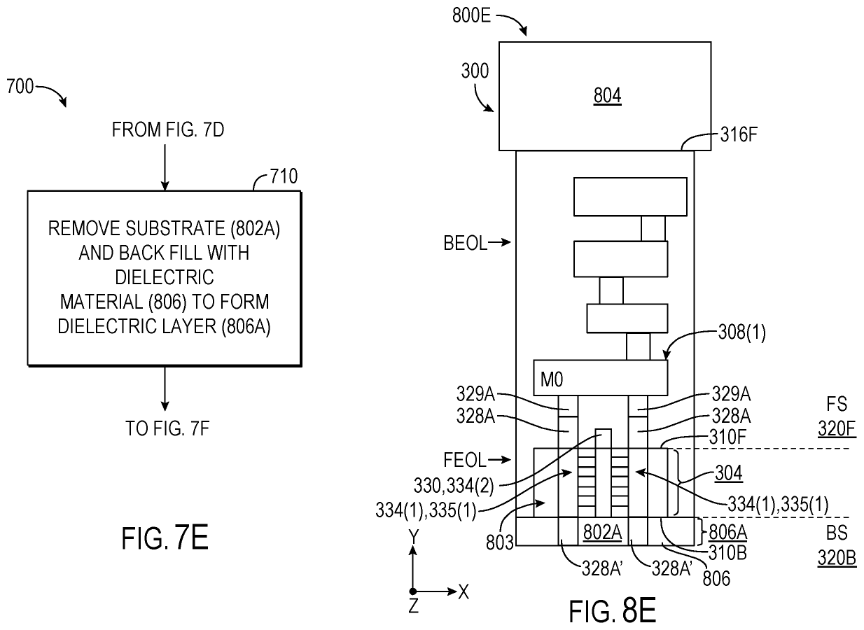

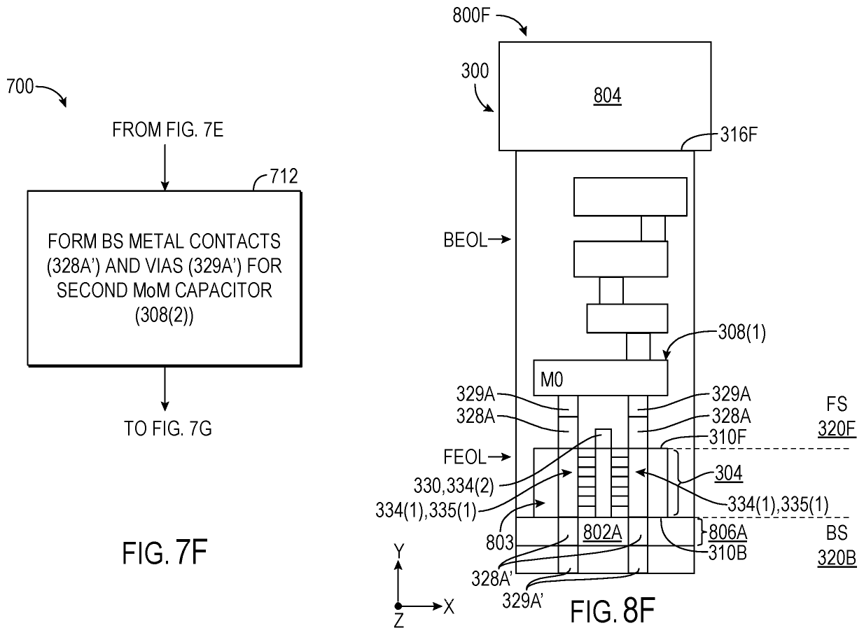

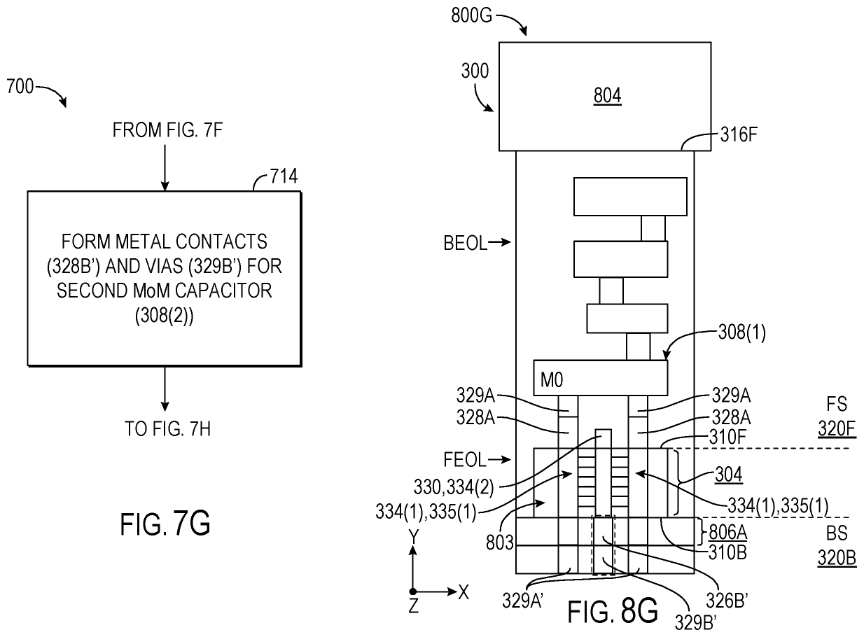

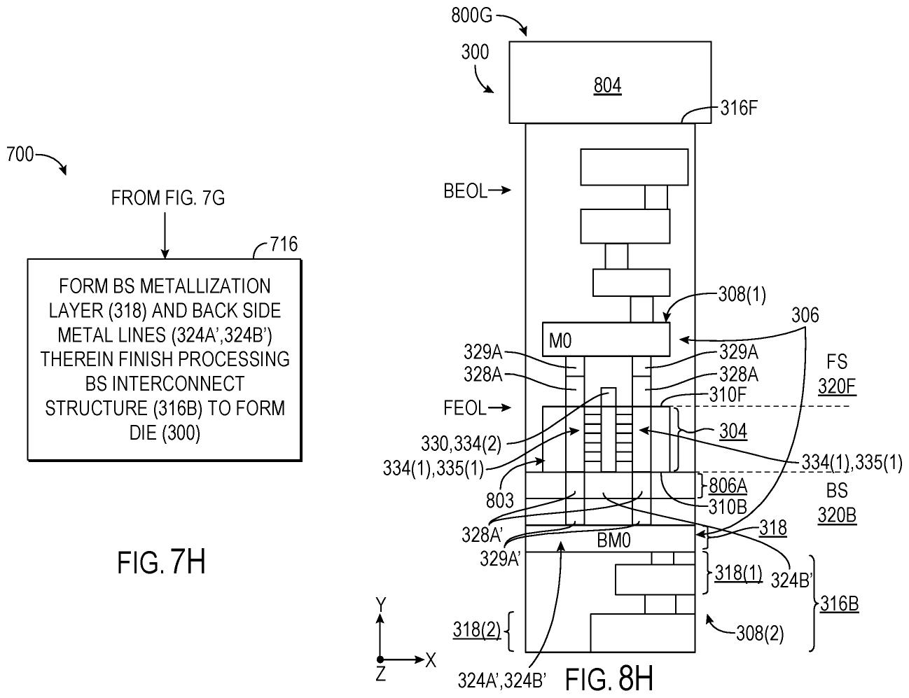

For example, FIGS. 7A-7H is a flowchart illustrating a fabrication process 700 of fabricating a die that includes a stacked MoM capacitor(s) that includes a first, front side, MoM capacitor formed on a front side of a semiconductor layer of the die and in front side metallization layers in a front side interconnect structure, coupled to a second, back side MoM capacitor formed on a back side of the semiconductor layer of the die in back side metallization layers in a back side interconnect structure including, but not limited to, the dies 300, 300(1), 300(2), 500 and stacked MoM capacitors 306, 506 in FIGS. 3A-5C. FIGS. 8A-8H are exemplary fabrication stages 800A-800H during fabrication of the die and its MoM capacitor according to the exemplary fabrication process 700 in FIGS. 7A-7H. The fabrication process 700 in FIGS. 7A-7H is discussed below with reference to the exemplary die 300 and its stacked MoM capacitor 306 in FIGS. 3A-3D, but such is not limiting and could be used to fabricate the dies 300, 300(1), 300(2), 500 and the stacked MoM capacitors 306, 506 in FIGS. 3A-5C.

In this regard, as shown in the exemplary fabrication stage 800A in FIG. 8A, a first step in the fabrication process 700 of fabricating the die 300 and its stacked MoM capacitor 306 is to perform the FEOL and BEOL processing to form the semiconductor layer 304 on a substrate 802 and to form the front side interconnect structure 316F adjacent to the semiconductor layer 304 that includes the first MoM capacitor 308(1) (block 702 in FIG. 7A). The formation of the semiconductor layer 304 also includes forming a semiconductor device 803 that can include structures that would be fabricated in a FET, such as the epitaxial layers 335(1). The first MoM capacitor 308(1) is formed in the front side interconnect structure 316F. As previously discussed, the epitaxial layers 335(1) may be used as the first conductive structure 334(1) to couple the first MoM capacitor 308(1) to a second, back side MoM capacitor 308(2).

Then, as shown in the exemplary fabrication stage 800B in FIG. 8B, a next step in the fabrication process 700 of fabricating the die 300 and its stacked MoM capacitor 306 can be to attach a carrier wafer 804 to the front side interconnect structure 316F to support the die 300 for further processing to form the back side interconnect structure 316B on the back side 310B of the semiconductor layer 304 (block 704 in FIG. 7B). Then, as shown in the exemplary fabrication stage 800C in FIG. 8C, a next step in the fabrication process 700 of fabricating the die 300 and its stacked MoM capacitor 306 is to grind down the substrate 802 to substrate 802A (block 706 in FIG. 7C). For example, the substrate 802A may be thinned by grinding the substrate 802 followed by a chemical or mechanical polish. Then, as shown in the exemplary fabrication stage 800D in FIG. 8D, a next step in the fabrication process 700 of fabricating the die 300 and its stacked MoM capacitor 306 can be to form back side, third metal contacts 328A′ that can be used to couple to metallization layers in the back side interconnect structure 316B to be formed to couple the first MoM capacitor 308(1) to the second MoM capacitor 308(2) (block 708 in FIG. 7D). This can involve etching the substrate 802A to form the back side, third metal contacts 328A′ using a barrier deposition with a metal fill and chemical or mechanical polishing.

Then, as shown in the exemplary fabrication stage 800E in FIG. 8E, a next step in the fabrication process 700 of fabricating the die 300 and its stacked MoM capacitor 306 can be to remove the substrate 802A and back fill it with a dielectric material 806 followed by a chemical or mechanical polish to form a dielectric layer 806A between the semiconductor layer 304 and the to be formed back side interconnect structure 316B (block 710 in FIG. 7E). This is to prepare for the formation of metallization layers for the back side interconnect structure 316B on the back side 320B of the die 300. Then, as shown in the exemplary fabrication stage 800F in FIG. 8F, a next step in the fabrication process 700 of fabricating the die 300 and its stacked MoM capacitor 306 can be to form the back side, third metal contacts 328A′ and vias 329A′ adjacent to the dielectric layer 806A for coupling third metal lines 324A′ in a back side metallization layer 318 as part of the third conductive finger structures 322A′used to form the second MoM capacitor 308(2) (block 712 in FIG. 7F). Then, as shown in the exemplary fabrication stage 800G in FIG. 8G, a next step in the fabrication process 700 of fabricating the die 300 and its stacked MoM capacitor 306 can be to form the back side, fourth gate contacts 328B′ and back side vias 329B′ to be coupled to the gate 330 as part of the second MoM capacitor 308(2) (block 714 in FIG. 7G).

Then, as shown in the exemplary fabrication stage 800H in FIG. 8H, a next step in the fabrication process 700 of fabricating the die 300 and its stacked MoM capacitor 306 can be to form the back side metallization layer 318 as part of the formation of the back side interconnect structure 316B and to form the back side, third and fourth metal lines 324A′, 324B′ therein and coupled to the respective vias 329A′, 329B′ to second MoM capacitor 308(2). Other back side metallization layers 318(1), 318(2) can also be formed on the back side 320B adjacent to the back side metallization layer 318 to finish the fabrication of the die 300 with its stacked MoM capacitor 306 with its first MoM capacitor 308(1) coupled to the second MoM capacitor 308(2) (block 716 in FIG. 7G).

Note that in some examples, the MoM capacitors discussed above can be formed as part of an interconnect structure, meaning that certain metal lines and structures in the interconnect structure that are interconnected to each other form a MoM capacitor. Note that an interconnect structure can either fully or partially contain a MoM capacitor. If an interconnect structure fully contains a MoM capacitor, the metal structures forming the MoM capacitor are fully provided (i.e., contained) in the interconnect structure. If an interconnect structure partially contains a MoM capacitor, the metal structures forming the MoM capacitor are partially provided (i.e., contained) in the interconnect structure, but other metal structures forming part of the MoM capacitor may be outside of the interconnect structure, such as in an adjacent cell circuit or other adjacent structure. In the examples discussed above, and when it is stated that an interconnect structure at least partially includes a MoM capacitor, this means that the interconnect structure either fully or partially includes the MoM capacitor. Also, when it is stated that an interconnect structure “comprises” a MoM capacitor, this means that the interconnect structure can either fully or partially include the MoM capacitor.

It should be understood that the terms “first,” “second,” “third,” etc., where used herein, are relative terms and are not meant to limit or imply a strict orientation. It should also be understood that that the terms “front side,” “top,” “upper,” “above,” and “back side,” “bottom,” “lower,” “below,” where used herein, are relative terms and are not meant to limit or imply a strict orientation. A “front side,” “top,” or “upper” or “above” referenced element does not always need to be oriented to be above a “bottom side,” “bottom,” or “lower,” or “below” referenced element with respect to ground, and vice versa. An element referenced as “front side,” “top,” “upper,” “above,” may be on top or bottom relative to that of an element referenced as “back side,” “bottom,” “lower,” “below,” may be on top or bottom relative to that example only and the particular illustrated example. An element referenced as “front side,” “top,” “upper” or “above” or “back side,” “bottom,” “lower,” “below,” another element does not have to be with respect to ground, and vice versa. An element referenced as “front side,” “top,” “upper” or “above” may be above or below such other referenced element, relative to that example only and the particular illustrated example.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

A die that includes a stacked MoM capacitor(s) that includes a first, front side, MoM capacitor formed on a front side of a semiconductor layer of the die and in front side metallization layers in a front side interconnect structure, coupled to a second, back side MoM capacitor formed on a back side of the semiconductor layer of the die in back side metallization layers in a back side interconnect structure, including, but not limited to, the dies 300, 300(1), 300(2), 500 and stacked MoM capacitors 306, 506 in FIGS. 3A-5C and 8H, and that can be fabricated according to a fabrication process, including, but not limited to, the exemplary fabrication processes 600, 700 in FIGS. 6 and 7A-7H, and 10A-10B, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

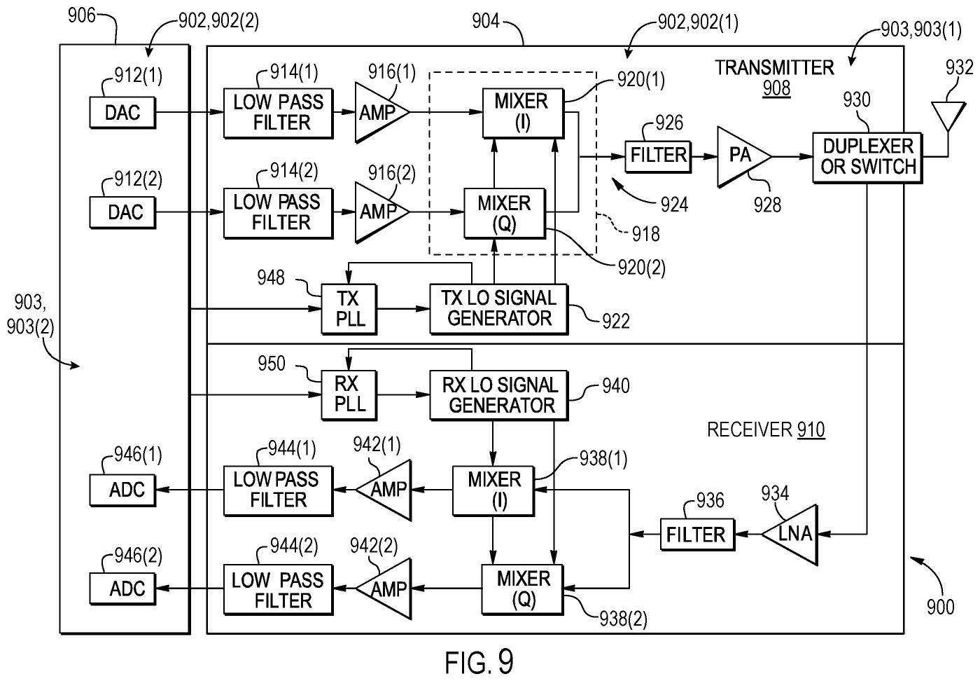

In this regard, FIG. 9 illustrates an exemplary wireless communications device 900 that includes one or more IC packages 902, 902(1), 902(2) that each include a die 903, 903(1), 903(2), including, but not limited to, the dies 300, 300(1), 300(2), 500 and the stacked MoM capacitors 306, 506 in FIGS. 3A-5C and 8H, wherein the die 903, 903(1), 903(2) can include a stacked MoM capacitor(s), like the stacked MoM capacitors 306, 506 in FIGS. 3A-5C and 8H for example, that includes a first, front side, MoM capacitor formed on a front side of a semiconductor layer of the die and in front side metallization layers in a front side interconnect structure, coupled to a second, back side MoM capacitor formed on a back side of the semiconductor layer of the die in back side metallization layers in a back side interconnect structure. The IC packages 902, 902(1), 902(2) and their dies 903, 903(1), 903(2) can be fabricated according to a fabrication process, including, but not limited to, the exemplary fabrication processes 600, 700 in FIGS. 6 and 7A-7H, and according to any aspects disclosed herein.

The wireless communications device 900 may include or be provided in any of the above-referenced devices, as examples. As shown in FIG. 9, the wireless communications device 900 includes a transceiver 904 and a data processor 906. The data processor 906 may include a memory to store data and program codes. The transceiver 904 includes a transmitter 908 and a receiver 910 that support bi-directional communications. In general, the wireless communications device 900 may include any number of transmitters 908 and/or receivers 910 for any number of communication systems and frequency bands. All or a portion of the transceiver 904 may be implemented on one or more analog ICs, RF ICs (RFICs), mixed-signal ICs, etc.

The transmitter 908 or the receiver 910 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 910. In the direct-conversion architecture, a signal is frequency-converted between RF and baseband in one stage. The super-heterodyne and direct-conversion architectures may use different circuit blocks and/or have different requirements. In the wireless communications device 900 in FIG. 9, the transmitter 908 and the receiver 910 are implemented with the direct-conversion architecture.

In the transmit path, the data processor 906 processes data to be transmitted and provides I and Q analog output signals to the transmitter 908. In the exemplary wireless communications device 900, the data processor 906 includes digital-to-analog converters (DACs) 912(1), 912(2) for converting digital signals generated by the data processor 906 into the I and Q analog output signals, e.g., I and Q output currents, for further processing.

Within the transmitter 908, lowpass filters 914(1), 914(2) filter the I and Q analog output signals, respectively, to remove undesired signals caused by the prior digital-to-analog conversion. Amplifiers (AMPs) 916(1), 916(2) amplify the signals from the lowpass filters 914(1), 914(2), respectively, and provide I and Q baseband signals. An upconverter 918 upconverts the I and Q baseband signals with I and Q transmit (TX) local oscillator (LO) signals through mixers 920(1), 920(2) from a TX LO signal generator 922 to provide an upconverted signal 924. A filter 926 filters the upconverted signal 924 to remove undesired signals caused by the frequency upconversion as well as noise in a receive frequency band. A power amplifier (PA) 928 amplifies the upconverted signal 924 from the filter 926 to obtain the desired output power level and provides a transmit RF signal. The transmit RF signal is routed through a duplexer or switch 930 and transmitted via an antenna 932.

In the receive path, the antenna 932 receives signals transmitted by base stations and provides a received RF signal, which is routed through the duplexer or switch 930 and provided to a low noise amplifier (LNA) 934. The duplexer or switch 930 is designed to operate with a specific receive (RX)-to-TX duplexer frequency separation, such that RX signals are isolated from TX signals. The received RF signal is amplified by the LNA 934 and filtered by a filter 936 to obtain a desired RF input signal. Downconversion mixers 938(1), 938(2) mix the output of the filter 936 with I and Q RX LO signals (i.e., LO_I and LO_Q) from an RX LO signal generator 940 to generate I and Q baseband signals. The I and Q baseband signals are amplified by AMPs 942(1), 942(2) and further filtered by lowpass filters 944(1), 944(2) to obtain I and Q analog input signals, which are provided to the data processor 906. In this example, the data processor 906 includes analog-to-digital converters (ADCs) 946(1), 946(2) for converting the analog input signals into digital signals to be further processed by the data processor 906.

In the wireless communications device 900 of FIG. 9, the TX LO signal generator 922 generates the I and Q TX LO signals used for frequency upconversion, while the RX LO signal generator 940 generates the I and Q RX LO signals used for frequency downconversion. Each LO signal is a periodic signal with a particular fundamental frequency. A TX phase-locked loop (PLL) circuit 948 receives timing information from the data processor 906 and generates a control signal used to adjust the frequency and/or phase of the TX LO signals from the TX LO signal generator 922. Similarly, an RX PLL circuit 950 receives timing information from the data processor 906 and generates a control signal used to adjust the frequency and/or phase of the RX LO signals from the RX LO signal generator 940.

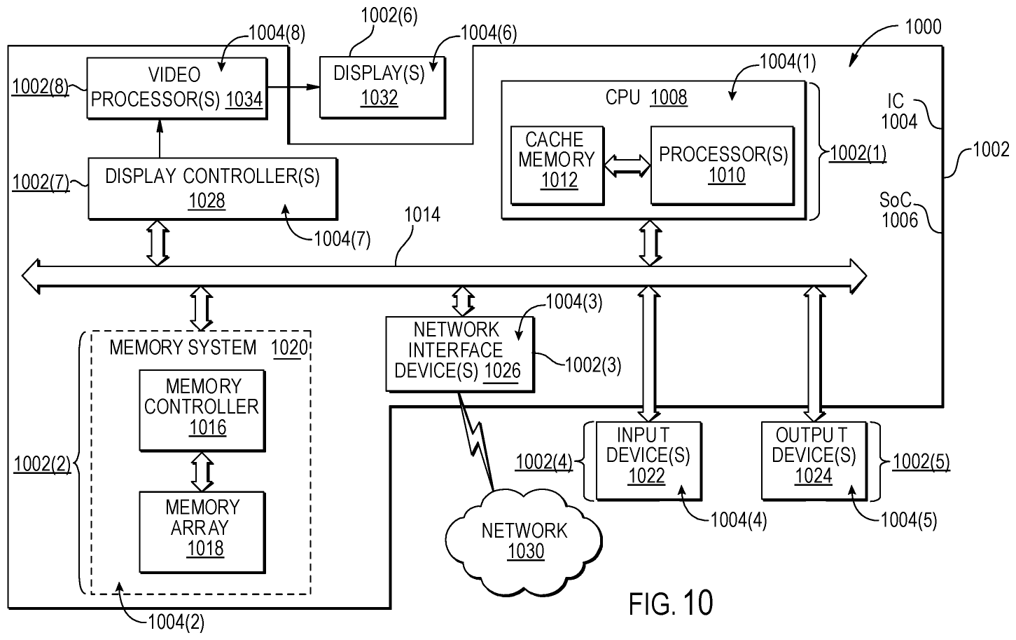

FIG. 10 illustrates an example of a processor-based system 1000 that includes one or more IC packages 1002, 1002(1)-1002(8) that each include a die 1004, 1004(1)-1004(8) including, but not limited to, the dies 300, 300(1), 300(2), 500 and the stacked MoM capacitors 306, 506 in FIGS. 3A-5C and 8H, wherein the die 1004, 1004(1)-1004(8) can include a stacked MoM capacitor(s), like the stacked MoM capacitors 306, 506 in FIGS. 3A-5C and 8H for example, that includes a first, front side, MoM capacitor formed on a front side of the semiconductor layer of the die and in front side metallization layers in a front side interconnect structure, coupled to a second, back side MoM capacitor formed on the back side of the semiconductor layer of the die in back side metallization layers in a back side interconnect structure. The IC packages 902, 902(1), 902(2) and their dies 903, 903(1), 903(2) can be fabricated according to a fabrication process, including, but not limited to, the exemplary fabrication processes 600, 700 in FIGS. 6 and 7A-7H, and according to any aspects disclosed herein.

In this example, the processor-based system 1000 may include a die 1004 that is included in an IC package 1002, such as a system-on-a-chip (SoC) 1006. The processor-based system 1000 includes a CPU 1008 that includes one or more processors 1010, which may also be referred to as CPU cores or processor cores. The CPU 1008 can be provided in an IC package 1002(1) that includes the die 1004(1). The CPU 1008 may have cache memory 1012 coupled to the CPU 1008 for rapid access to temporarily stored data. The CPU 1008 is coupled to a system bus 1014 and can intercouple master and slave devices included in the processor-based system 1000. As is well known, the CPU 1008 communicates with these other devices by exchanging address, control, and data information over the system bus 1014. For example, the CPU 1008 can communicate bus transaction requests to a memory controller 1016 as an example of a slave device. Although not illustrated in FIG. 10, multiple system buses 1014 could be provided, wherein each system bus 1014 constitutes a different fabric.

Other master and slave devices can be connected to the system bus 1014. As illustrated in FIG. 10, these devices can include a memory system 1020 that includes the memory controller 1016 and a memory array(s) 1018, one or more input devices 1022, one or more output devices 1024, one or more network interface devices 1026, and one or more display controllers 1028, as examples. The memory system 1020 can be provided in an IC package 1002(2) that includes the die 1004(2). The network interface devices 1026 can be provided in an IC package 1002(3) that includes the die 1004(3). Each of the memory system 1020, the one or more input devices 1022, the one or more output devices 1024, the one or more network interface devices 1026, and the one or more display controllers 1028 can be provided in the same or different circuit packages. The input devices 1022 and/or the output devices 1024 can be provided in a respective IC package 1002(4), 1002(5) that includes a respective die 1004(4), 1004(5). The input device(s) 1022 can include any type of input device, including, but not limited to, input keys, switches, voice processors, etc. The output device(s) 1024 can include any type of output device, including, but not limited to, audio, video, other visual indicators, etc. The network interface device(s) 1026 can be any device configured to allow exchange of data to and from a network 1030. The network 1030 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1026 can be configured to support any type of communications protocol desired.

The CPU 1008 may also be configured to access the display controller(s) 1028 over the system bus 1014 to control information sent to one or more displays 1032. The display 1032 can be provided in an IC package 1002(6) that includes the die 1004(6). The display controller(s) 1028 sends information to the display(s) 1032 to be displayed via one or more video processors 1034, which process the information to be displayed into a format suitable for the display(s) 1032. The display controller(s) 1028 and video processor(s) 1034 can be provided in a respective IC package 1002(7), 1002(8) that includes the dies 1004(7), 1004(8), or be provided in the same IC package 1002, or be provided in the same IC package 1002(1) containing the CPU 1008 as an example. The display(s) 1032 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. A semiconductor die, comprising:
a semiconductor layer extending in a first direction, the semiconductor layer comprising a front side and a back side opposite the front side in a second direction orthogonal to the first direction;
a front side interconnect structure adjacent to the front side of the semiconductor layer in the second direction,
   the front side interconnect structure comprising a first metal-oxide-metal (MoM) capacitor;
a back side interconnect structure adjacent to the back side of the semiconductor layer in the second direction,
   the back side interconnect structure comprising a second MoM capacitor; and
a stacked MoM capacitor, comprising:
   the first MoM capacitor; and
   the second MoM capacitor coupled to the first MoM capacitor.
2. The semiconductor die of clause 1, wherein:
the front side interconnect structure further comprises a front side metallization layer comprising the first MoM capacitor and extending in the first direction; and
the back side interconnect structure further comprises a back side metallization layer comprising the second MoM capacitor and extending in the first direction.
3. The semiconductor die of clause 2, wherein:
the first MoM capacitor comprises:
   a first metal line in the front side metallization layer; and
   a first conductive finger structure in the front side metallization layer, the first conductive finger structure comprising a plurality of first finger metal lines parallel to each other and coupled to the first metal line;
   a second metal line in the front side metallization layer; and
   a second conductive finger structure in the front side metallization layer, the second conductive finger structure comprising a plurality of second finger metal lines parallel to each other and coupled to the second metal line,
   the first conductive finger structure interdigitated with the second conductive finger structure; and
the second MoM capacitor comprises:
   a third metal line in the back side metallization layer; and
   a third conductive finger structure in the back side metallization layer, the third conductive finger structure comprising a plurality of third finger metal lines parallel to each other and coupled to the third metal line;
   a fourth metal line in the back side metallization layer; and
   a fourth conductive finger structure in the back side metallization layer, the fourth conductive finger structure comprising a plurality of fourth finger metal lines parallel to each other and coupled to the fourth metal line,
   the third conductive finger structure interdigitated with the fourth conductive finger structure.
4. The semiconductor die of any of clauses 1-3, wherein the stacked MoM capacitor further comprises one or more first conductive structures each extending in the second direction and coupled to the first MoM capacitor and the second MoM capacitor.
5. The semiconductor die of any of clauses 1-4, wherein the one or more first conductive structures comprise one or more vias.
6. The semiconductor die of any of clauses 1-4, wherein the one or more first conductive structures comprise one or more metal contacts.
7. The semiconductor die of any of clauses 1, 2, and 4-6, further comprising:
a cell circuit, comprising:
   a diffusion region in the semiconductor layer;
   a first metal line in the front side interconnect structure;
   a second metal line in the front side interconnect structure;
   a third metal line in the back side interconnect structure;
   a fourth metal line in the back side interconnect structure;
   a plurality of first finger metal lines coupled to the first metal line and adjacent to the semiconductor layer; and
   a plurality of second finger metal lines coupled to the second metal line and adjacent to the semiconductor layer,
      the plurality of second finger metal lines interdigitated with the plurality of first finger metal lines;
   a plurality of third finger metal lines coupled to the third metal line and the semiconductor layer; and
   a plurality of fourth finger metal lines coupled to the fourth metal line and the semiconductor layer,
      the plurality of fourth finger metal lines interdigitated with the plurality of third finger metal lines;
wherein:
   the first MoM capacitor comprises:
      a first conductive finger structure comprising the first metal line and the plurality of first finger metal lines; and
      a second conductive finger structure comprising the second metal line and the plurality of second finger metal lines; and
   the second MoM capacitor comprises:
      a third conductive finger structure comprising the third metal line and the plurality of third finger metal lines; and
      a fourth conductive finger structure comprising the fourth metal line and the plurality of fourth finger metal lines.
8. The semiconductor die of clause 7, wherein the stacked MoM capacitor further comprises one or more through silicon vias (TSVs) each extending in the second direction through the semiconductor layer and coupled to the first MoM capacitor and the second MoM capacitor.
9. The semiconductor die of any of clauses 1, 2, and 4-6, further comprising:
a cell circuit, comprising:
   a diffusion region in the semiconductor layer;
   a first metal line in the front side interconnect structure, the first metal line at least partially intersecting the diffusion region in the second direction;
   a second metal line in the front side interconnect structure;
   a third metal line in the back side interconnect structure, the third metal line at least partially intersecting the diffusion region in the second direction;
   a fourth metal line in the back side interconnect structure;
   a plurality of first metal fingers coupled to the first metal line and the semiconductor layer; and
   a plurality of second metal fingers coupled to the second metal line and the semiconductor layer,
      the plurality of second metal fingers interdigitated with the plurality of first metal fingers;
   a plurality of third metal fingers coupled to the third metal line and the semiconductor layer; and
   a plurality of fourth metal fingers coupled to the fourth metal line and the semiconductor layer,
      the plurality of fourth metal fingers interdigitated with the plurality of third metal fingers;
the first MoM capacitor, comprising:
   a first conductive finger structure comprising the first metal line and the plurality of first metal fingers; and
   a second conductive finger structure comprising the second metal line and the plurality of second metal fingers; and
the second MoM capacitor, comprising:
   a third conductive finger structure comprising the third metal line and the plurality of third metal fingers; and
   a fourth conductive finger structure comprising the fourth metal line and the plurality of fourth metal fingers.
10. The semiconductor die of clause 9, wherein:
the first metal line and the third metal line at least partially intersect the diffusion region in the second direction; and
the second metal line and the fourth metal line do not intersect the diffusion region in the second direction.
11. The semiconductor die of clause 9 or 10, further comprising:
a plurality of first conductive structures extending in the second direction and coupling the plurality of first metal fingers to the plurality of third metal fingers; and
a plurality of second conductive structures extending in the second direction and coupling the plurality of second metal fingers to the plurality of fourth metal fingers.
12. The semiconductor die of clause 11, wherein:
the plurality of first conductive structures comprises a plurality of first epitaxial layers in the diffusion region;
the plurality of first metal fingers comprises a plurality of first metal contacts coupled to the plurality of first epitaxial layers; and
the plurality of third metal fingers comprises a plurality of second metal contacts coupled to the plurality of first epitaxial layers.
13. The semiconductor die of clause 12, wherein:
the cell circuit further comprises a plurality of gates;
the plurality of second metal fingers comprises the plurality of gates; and
the plurality of fourth metal fingers comprises the plurality of second metal contacts.
14. The semiconductor die of clause 13, wherein the stacked MoM capacitor further comprises a plurality of first semiconductor capacitors each comprising a first epitaxial layer of the plurality of first epitaxial layers adjacent to each gate of the plurality of gates.
15. The semiconductor die of clause 9, wherein:
the cell circuit further comprises a plurality of gates;
the plurality of second metal fingers comprises the plurality of gates; and
the plurality of fourth metal fingers comprises a plurality of second metal contacts.
16. The semiconductor die of clause 15, wherein:
the first MoM capacitor further comprises a plurality of first gate contacts coupled to the plurality of gates; and
the second MoM capacitor further comprises a plurality of second gate contacts coupled to the plurality of gates.
17. The semiconductor die of any of clauses 9-16, wherein the diffusion region comprises an N-type semiconductor material (N) field effect transistor (FET) (NFET) diffusion region.
18. The semiconductor die of any of clauses 9-16, wherein the diffusion region comprises a P-type semiconductor material (P) field effect transistor (FET) (PFET) diffusion region.
19. The semiconductor die of any of clauses 1, 2, and 4-6, further comprising:
a cell circuit, comprising:
   a first diffusion region in the semiconductor layer;
   a first metal line in the front side interconnect structure, the first metal line not intersecting the first diffusion region in the second direction;
   a second metal line in the front side interconnect structure, the second metal line not intersecting the first diffusion region in the second direction;
   a third metal line in the back side interconnect structure, the third metal line not intersecting the first diffusion region in the second direction;
   a fourth metal line in the back side interconnect structure, the fourth metal line not intersecting the first diffusion region in the second direction;
   a plurality of fifth metal lines coupled to the first metal line and adjacent to the semiconductor layer, the plurality of fifth metal lines intersecting the first diffusion region in the second direction; and
   a plurality of gates coupled to the second metal line and the semiconductor layer, the plurality of gates intersecting the first diffusion region in the second direction;
      the plurality of gates interdigitated with the plurality of fifth metal lines;
   a plurality of sixth metal lines coupled to the third metal line and adjacent to the semiconductor layer, the plurality of sixth metal lines interdigitated with the plurality of gates; and
the first MoM capacitor, comprising:
   a first conductive finger structure comprising the first metal line and the plurality of fifth metal lines; and
   a second conductive finger structure comprising the second metal line and the plurality of gates; and
the second MoM capacitor, comprising:
   a third conductive finger structure comprising the third metal line and the plurality of sixth metal lines; and
   a fourth conductive finger structure comprising the fourth metal line and the plurality of gates.
20. The semiconductor die of clause 19, further comprising:
a first conductive structure extending in the second direction and coupling the first metal line to the third metal line; and
a second conductive structure extending in the second direction and coupling the second metal line to the fourth metal line.
21 The semiconductor die of clause 20, wherein:
the first conductive structure comprises a first bar via coupled to the first metal line and the third metal line; and
the second conductive structure comprises a second bar via coupled to the second metal line and the fourth metal line.
22. The semiconductor die of clause 20 or 21, wherein:
the first MoM capacitor further comprises:
   a plurality of first gate contacts coupled to the plurality of gates and the second metal line; and
the second MoM capacitor further comprises:
   a plurality of second gate contacts coupled to the plurality of gates and the fourth metal line.
23 The semiconductor die of any of clauses 19-22, wherein:
the first diffusion region comprises a first N-type semiconductor material (N) field effect transistor (FET) (NFET) diffusion region; and
a second diffusion region comprises a second NFET diffusion region.
24. The semiconductor die of any of clauses 19-22, wherein:
the first diffusion region comprises a first P-type semiconductor material (P) field effect transistor (FET) (PFET) diffusion region; and
a second diffusion region comprises a second PFET diffusion region.
25. The semiconductor die of any of clauses 1-24 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
26. A method of fabricating a semiconductor die, comprising:
forming a semiconductor layer extending in a first direction, the semiconductor layer comprising a front side and a back side opposite the front side in a second direction orthogonal to the first direction;
forming a front side interconnect structure comprising a first metal-oxide-metal (MoM) capacitor and adjacent to the front side of the semiconductor layer in the second direction;
forming a back side interconnect structure comprising a second MoM capacitor and adjacent to the back side of the semiconductor layer in the second direction; and
forming a stacked MoM capacitor, comprising coupling the first MoM capacitor to the second MoM capacitor.
27. The method of clause 26, wherein:
forming the front side interconnect structure comprises forming a front side metallization layer comprising the first MoM capacitor and extending in the first direction and adjacent to the front side of the semiconductor layer in the second direction;
forming the back side interconnect structure a comprises forming a back side metallization layer comprising the second MoM capacitor and adjacent to the back side of the semiconductor layer in the second direction; and
wherein the first MoM capacitor comprises:
   a first metal line in the front side metallization layer; and
   a first conductive finger structure in the front side metallization layer, the first conductive finger structure comprising a plurality of first finger metal lines parallel to each other and coupled to the first metal line;
   a second metal line in the front side metallization layer; and
   a second conductive finger structure in the front side metallization layer, the second conductive finger structure comprising a plurality of second finger metal lines parallel to each other and coupled to the second metal line, such that the first conductive finger structure is interdigitated with the second conductive finger structure; and
wherein the second MoM capacitor comprises:
   a third metal line in the back side metallization layer; and
   a third conductive finger structure in the back side metallization layer, the third conductive finger structure comprising a plurality of third finger metal lines parallel to each other and coupled to the third metal line;
   a fourth metal line in the back side metallization layer; and
   a fourth conductive finger structure in the back side metallization layer, the fourth conductive finger structure comprising a plurality of fourth finger metal lines parallel to each other and coupled to the fourth metal line, such that the third conductive finger structure is interdigitated with the fourth conductive finger structure.
28. The method of clause 26, further comprising:
forming a cell circuit, comprising:
   forming diffusion region in the semiconductor layer;
   forming a first metal line in the front side interconnect structure;
   forming a second metal line in the front side interconnect structure;
   forming a third metal line in the back side interconnect structure;
   forming a fourth metal line in the back side interconnect structure;
   forming a plurality of first finger metal lines coupled to the first metal line and adjacent to the semiconductor layer; and
   forming a plurality of second finger metal lines coupled to the second metal line and adjacent to the semiconductor layer, such that the plurality of second finger metal lines is interdigitated with the plurality of first finger metal lines;
   forming a plurality of third finger metal lines coupled to the third metal line and the semiconductor layer; and
   a plurality of fourth finger metal lines coupled to the fourth metal line and the semiconductor layer, such that the plurality of fourth finger metal lines is interdigitated with the plurality of third finger metal lines;
wherein:
   the first MoM capacitor comprises:
      a first conductive finger structure comprising the first metal line and the plurality of first finger metal lines in the front side interconnect structure; and
      a second conductive finger structure comprising the second metal line and the plurality of second finger metal lines in the front side interconnect structure; and
   the second MoM capacitor comprises:
      a third conductive finger structure comprising the third metal line and the plurality of third finger metal lines in the back side interconnect structure; and
      a fourth conductive finger structure comprising the fourth metal line and the plurality of fourth finger metal lines in the back side interconnect structure.
29. The method of clause 26, further comprising:
forming a cell circuit, comprising:
   forming a diffusion region in the semiconductor layer;
   forming a first metal line in the front side interconnect structure, the first metal line at least partially intersecting the diffusion region in the second direction;
   forming a second metal line in the front side interconnect structure;
   forming a third metal line in the back side interconnect structure, the third metal line at least partially intersecting the diffusion region in the second direction;
   forming a fourth metal line in the back side interconnect structure;
   forming a plurality of first metal fingers coupled to the first metal line and the semiconductor layer; and
   forming a plurality of second metal fingers coupled to the second metal line and the semiconductor layer, such that the plurality of second metal fingers is interdigitated with the plurality of first metal fingers;
   forming a plurality of third metal fingers coupled to the third metal line and the semiconductor layer; and
   forming a plurality of fourth metal fingers coupled to the fourth metal line and the semiconductor layer, such that the plurality of fourth metal fingers is interdigitated with the plurality of third metal fingers;
wherein:
   the first MoM capacitor comprises:
      a first conductive finger structure comprising the first metal line and the plurality of first metal fingers in the front side interconnect structure; and
      a second conductive finger structure comprising the second metal line and the plurality of second metal fingers in the front side interconnect structure; and
   the second MoM capacitor comprises:
      a third conductive finger structure comprising the third metal line and the plurality of third metal fingers in the back side interconnect structure; and
      a fourth conductive finger structure comprising the fourth metal line and the plurality of fourth metal fingers in the back side interconnect structure.
30. The method of clause 26, further comprising:
forming a cell circuit, comprising:
   forming a first diffusion region in the semiconductor layer;
   forming a first metal line in the front side interconnect structure, the first metal line not intersecting the first diffusion region in the second direction;
   forming a second metal line in the front side interconnect structure, the second metal line not intersecting the first diffusion region in the second direction;
   forming a third metal line in the back side interconnect structure, the third metal line not intersecting the first diffusion region in the second direction;
   forming a fourth metal line in the back side interconnect structure, the fourth metal line not intersecting the first diffusion region in the second direction;
   forming a plurality of fifth metal lines coupled to the first metal line and adjacent to the semiconductor layer, the plurality of fifth metal lines intersecting the first diffusion region in the second direction; and
   forming a plurality of gates coupled to the second metal line and the semiconductor layer, the plurality of gates intersecting the first diffusion region in the second direction, such that the plurality of gates are interdigitated with the plurality of fifth metal lines;
   forming a plurality of sixth metal lines coupled to the third metal line and adjacent to the semiconductor layer, such that the plurality of sixth metal lines are interdigitated with the plurality of gates; and
wherein:
   the first MoM capacitor comprises:
      a first conductive finger structure comprising the first metal line and the plurality of fifth metal lines in the front side interconnect structure; and
      a second conductive finger structure comprising the second metal line and the plurality of gates in the front side interconnect structure; and
   the second MoM capacitor comprises:
      a third conductive finger structure comprising the third metal line and the plurality of sixth metal lines in the back side interconnect structure; and
      a fourth conductive finger structure comprising the fourth metal line and the plurality of gates in the back side interconnect structure.

What is claimed is:

1. A semiconductor die, comprising:
a semiconductor layer extending in a first direction, the semiconductor layer comprising a front side and a back side opposite the front side in a second direction orthogonal to the first direction;
a front side interconnect structure adjacent to the front side of the semiconductor layer in the second direction,
the front side interconnect structure comprising a first metal-oxide-metal (MoM) capacitor;
a back side interconnect structure adjacent to the back side of the semiconductor layer in the second direction,
the back side interconnect structure comprising a second MoM capacitor; and
a stacked MoM capacitor, comprising:
the first MoM capacitor; and
the second MoM capacitor coupled to the first MoM capacitor.

2. The semiconductor die of claim 1, wherein:
the front side interconnect structure further comprises a front side metallization layer comprising the first MoM capacitor and extending in the first direction; and
the back side interconnect structure further comprises a back side metallization layer comprising the second MoM capacitor and extending in the first direction.

3. The semiconductor die of claim 2, wherein:
the first MoM capacitor comprises:
a first metal line in the front side metallization layer; and
a first conductive finger structure in the front side metallization layer, the first conductive finger structure comprising a plurality of first finger metal lines parallel to each other and coupled to the first metal line;
a second metal line in the front side metallization layer; and
a second conductive finger structure in the front side metallization layer, the second conductive finger structure comprising a plurality of second finger metal lines parallel to each other and coupled to the second metal line,
the first conductive finger structure interdigitated with the second conductive finger structure; and
the second MoM capacitor comprises:
a third metal line in the back side metallization layer; and
a third conductive finger structure in the back side metallization layer, the third conductive finger structure comprising a plurality of third finger metal lines parallel to each other and coupled to the third metal line;
a fourth metal line in the back side metallization layer; and
a fourth conductive finger structure in the back side metallization layer, the fourth conductive finger structure comprising a plurality of fourth finger metal lines parallel to each other and coupled to the fourth metal line,
the third conductive finger structure interdigitated with the fourth conductive finger structure.

4. The semiconductor die of claim 1, wherein the stacked MoM capacitor further comprises one or more first conductive structures each extending in the second direction and coupled to the first MoM capacitor and the second MoM capacitor.

5. The semiconductor die of claim 1, further comprising:
a cell circuit, comprising:
a diffusion region in the semiconductor layer;
a first metal line in the front side interconnect structure;
a second metal line in the front side interconnect structure;
a third metal line in the back side interconnect structure;
a fourth metal line in the back side interconnect structure;
a plurality of first finger metal lines coupled to the first metal line and adjacent to the semiconductor layer; and
a plurality of second finger metal lines coupled to the second metal line and adjacent to the semiconductor layer,
the plurality of second finger metal lines interdigitated with the plurality of first finger metal lines;
a plurality of third finger metal lines coupled to the third metal line and the semiconductor layer; and
a plurality of fourth finger metal lines coupled to the fourth metal line and the semiconductor layer,
the plurality of fourth finger metal lines interdigitated with the plurality of third finger metal lines;
wherein:
the first MoM capacitor comprises:
a first conductive finger structure comprising the first metal line and the plurality of first finger metal lines; and
a second conductive finger structure comprising the second metal line and the plurality of second finger metal lines; and
the second MoM capacitor comprises:
a third conductive finger structure comprising the third metal line and the plurality of third finger metal lines; and
a fourth conductive finger structure comprising the fourth metal line and the plurality of fourth finger metal lines.

6. The semiconductor die of claim 1, further comprising:
a cell circuit, comprising:
a diffusion region in the semiconductor layer;
a first metal line in the front side interconnect structure, the first metal line at least partially intersecting the diffusion region in the second direction;
a second metal line in the front side interconnect structure;
a third metal line in the back side interconnect structure, the third metal line at least partially intersecting the diffusion region in the second direction;
a fourth metal line in the back side interconnect structure;
a plurality of first metal fingers coupled to the first metal line and the semiconductor layer; and
a plurality of second metal fingers coupled to the second metal line and the semiconductor layer,
the plurality of second metal fingers interdigitated with the plurality of first metal fingers;
a plurality of third metal fingers coupled to the third metal line and the semiconductor layer; and
a plurality of fourth metal fingers coupled to the fourth metal line and the semiconductor layer,
the plurality of fourth metal fingers interdigitated with the plurality of third metal fingers;
the first MoM capacitor, comprising:
a first conductive finger structure comprising the first metal line and the plurality of first metal fingers; and
a second conductive finger structure comprising the second metal line and the plurality of second metal fingers; and
the second MoM capacitor, comprising:
a third conductive finger structure comprising the third metal line and the plurality of third metal fingers; and
a fourth conductive finger structure comprising the fourth metal line and the plurality of fourth metal fingers.

7. The semiconductor die of claim 6, wherein:
the first metal line and the third metal line at least partially intersect the diffusion region in the second direction; and
the second metal line and the fourth metal line do not intersect the diffusion region in the second direction.

8. The semiconductor die of claim 6, further comprising:
a plurality of first conductive structures extending in the second direction and coupling the plurality of first metal fingers to the plurality of third metal fingers; and
a plurality of second conductive structures extending in the second direction and coupling the plurality of second metal fingers to the plurality of fourth metal fingers.

9. The semiconductor die of claim 8, wherein:
the cell circuit further comprises a plurality of gates;
the plurality of second metal fingers comprises the plurality of gates; and
the plurality of fourth metal fingers comprises a plurality of second metal contacts.

10. The semiconductor die of claim 9, wherein the stacked MoM capacitor further comprises a plurality of first semiconductor capacitors each comprising a first epitaxial layer of a plurality of first epitaxial layers adjacent to each gate of the plurality of gates.

11. The semiconductor die of claim 6, wherein:
the cell circuit further comprises a plurality of gates;
the plurality of second metal fingers comprises the plurality of gates; and
the plurality of fourth metal fingers comprises a plurality of second metal contacts.

12. The semiconductor die of claim 11, wherein:
the first MoM capacitor further comprises a plurality of first gate contacts coupled to the plurality of gates; and
the second MoM capacitor further comprises a plurality of second gate contacts coupled to the plurality of gates.

13. The semiconductor die of claim 1, further comprising:
a cell circuit, comprising:
a first diffusion region in the semiconductor layer;
a first metal line in the front side interconnect structure, the first metal line not intersecting the first diffusion region in the second direction;
a second metal line in the front side interconnect structure, the second metal line not intersecting the first diffusion region in the second direction;
a third metal line in the back side interconnect structure, the third metal line not intersecting the first diffusion region in the second direction;
a fourth metal line in the back side interconnect structure, the fourth metal line not intersecting the first diffusion region in the second direction;
a plurality of fifth metal lines coupled to the first metal line and adjacent to the semiconductor layer, the plurality of fifth metal lines intersecting the first diffusion region in the second direction; and
a plurality of gates coupled to the second metal line and the semiconductor layer, the plurality of gates intersecting the first diffusion region in the second direction;
the plurality of gates interdigitated with the plurality of fifth metal lines;
a plurality of sixth metal lines coupled to the third metal line and adjacent to the semiconductor layer, the plurality of sixth metal lines interdigitated with the plurality of gates; and
the first MoM capacitor, comprising:
a first conductive finger structure comprising the first metal line and the plurality of fifth metal lines; and
a second conductive finger structure comprising the second metal line and the plurality of gates; and
the second MoM capacitor, comprising:
a third conductive finger structure comprising the third metal line and the plurality of sixth metal lines; and
a fourth conductive finger structure comprising the fourth metal line and the plurality of gates.

14. The semiconductor die of claim 13, further comprising:
a first conductive structure extending in the second direction and coupling the first metal line to the third metal line; and
a second conductive structure extending in the second direction and coupling the second metal line to the fourth metal line.

15. The semiconductor die of claim 14, wherein:
the first conductive structure comprises a first bar via coupled to the first metal line and the third metal line; and
the second conductive structure comprises a second bar via coupled to the second metal line and the fourth metal line.

16. The semiconductor die of claim 14, wherein:
the first MoM capacitor further comprises:
a plurality of first gate contacts coupled to the plurality of gates and the second metal line; and
the second MoM capacitor further comprises:
a plurality of second gate contacts coupled to the plurality of gates and the fourth metal line.

17. The semiconductor die of claim 1 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

18. A method of fabricating a semiconductor die, comprising:
forming a semiconductor layer extending in a first direction, the semiconductor layer comprising a front side and a back side opposite the front side in a second direction orthogonal to the first direction;
forming a front side interconnect structure comprising a first metal-oxide-metal (MoM) capacitor and adjacent to the front side of the semiconductor layer in the second direction;
forming a back side interconnect structure comprising a second MoM capacitor and adjacent to the back side of the semiconductor layer in the second direction; and
forming a stacked MoM capacitor, comprising coupling the first MoM capacitor to the second MoM capacitor.

19. The method of claim 18, wherein:
forming the front side interconnect structure comprises forming a front side metallization layer comprising the first MoM capacitor and extending in the first direction and adjacent to the front side of the semiconductor layer in the second direction;
forming the back side interconnect structure comprises forming a back side metallization layer comprising the second MoM capacitor and adjacent to the back side of the semiconductor layer in the second direction; and
wherein the first MoM capacitor comprises:
a first metal line in the front side metallization layer; and
a first conductive finger structure in the front side metallization layer, the first conductive finger structure comprising a plurality of first finger metal lines parallel to each other and coupled to the first metal line;
a second metal line in the front side metallization layer; and
a second conductive finger structure in the front side metallization layer, the second conductive finger structure comprising a plurality of second finger metal lines parallel to each other and coupled to the second metal line, such that the first conductive finger structure is interdigitated with the second conductive finger structure; and
wherein the second MoM capacitor comprises:
a third metal line in the back side metallization layer; and
a third conductive finger structure in the back side metallization layer, the third conductive finger structure comprising a plurality of third finger metal lines parallel to each other and coupled to the third metal line;
a fourth metal line in the back side metallization layer; and
a fourth conductive finger structure in the back side metallization layer, the fourth conductive finger structure comprising a plurality of fourth finger metal lines parallel to each other and coupled to the fourth metal line, such that the third conductive finger structure is interdigitated with the fourth conductive finger structure.

20. The method of claim 18, further comprising:
forming a cell circuit, comprising:
forming diffusion region in the semiconductor layer;
forming a first metal line in the front side interconnect structure;
forming a second metal line in the front side interconnect structure;
forming a third metal line in the back side interconnect structure;
forming a fourth metal line in the back side interconnect structure;
forming a plurality of first finger metal lines coupled to the first metal line and adjacent to the semiconductor layer; and
forming a plurality of second finger metal lines coupled to the second metal line and adjacent to the semiconductor layer, such that the plurality of second finger metal lines is interdigitated with the plurality of first finger metal lines;
forming a plurality of third finger metal lines coupled to the third metal line and the semiconductor layer; and
a plurality of fourth finger metal lines coupled to the fourth metal line and the semiconductor layer, such that the plurality of fourth finger metal lines is interdigitated with the plurality of third finger metal lines;
wherein:
the first MoM capacitor comprises:
a first conductive finger structure comprising the first metal line and the plurality of first finger metal lines in the front side interconnect structure; and
a second conductive finger structure comprising the second metal line and the plurality of second finger metal lines in the front side interconnect structure; and
the second MoM capacitor comprises:
a third conductive finger structure comprising the third metal line and the plurality of third finger metal lines in the back side interconnect structure; and
a fourth conductive finger structure comprising the fourth metal line and the plurality of fourth finger metal lines in the back side interconnect structure.
